(19) United States
(12) Patent Application Publication
(10) Pub. No.: US 2016/0351740 A1
(43) Pub. Date: Dec. 1, 2016

(54) SOLAR CELL MODULE AND SOLAR CELL DEVICE

(71) Applicant: KYOCERA CORPORATION, Kyoto (JP)

(72) Inventors: Yuta NISHIO, Shiga (JP); Taiki Yoshimura, Mie (JP)

(21) Appl. No.: 15/166,087

(22) Filed: May 26, 2016

(30) Foreign Application Priority Data
May 28, 2015 (JP) 2015-108485
May 26, 2016 (JP) 2016-105270

(51) Int. Cl. H01L 31/048; H02S 30/10; H01L 31/049

(52) U.S. Cl. CPC H01L 31/0481; H01L 31/049; H02S 30/10

(57) ABSTRACT

A solar cell module includes a light-transmitting substrate and solar cell element groups. Each solar cell element group includes solar cell elements aligned in a first direction and each having rectangular first and second surfaces, and a wiring material electrically connecting a first solar cell element and a second solar cell element adjacent to each other in the first direction. The solar cell element groups are aligned in a second direction perpendicular to the first direction. In each solar cell element, first and second side parts each located along the second direction have a length in the second direction larger than the length in the first direction of third and fourth side parts each located along the first direction. The light-transmitting substrate covers the solar cell element groups from the first surface side and has a short side along the first direction and a long side along the second direction.

### CROSS-REFERENCE TO RELATED APPLICATIONS

The present application claims priority under 35 U.S.C. §119 to Japanese Patent Application Nos. 2015-108485 entitled “Solar cell module and solar cell device using the same” filed on May 28, 2015, and 2016-105270 entitled “Solar cell module and solar cell device” filed on May 26, 2016. The whole contents of these applications in their entirety are incorporated to this specification by reference.

### FIELD

Embodiments of the present disclosure relate to a solar cell module and a solar cell device using the solar cell module.

### BACKGROUND

A solar cell module is generally manufactured by stacking and laminating a front surface cover material, a solar cell element, and a back surface cover material.

Required characteristics of the solar cell module are to produce high output. In a solar cell module suggested in relation thereto, two divided solar cell elements are connected in series to reduce a current flowing in one solar cell element. This reduces resistance loss to produce higher output (see Japanese Patent Application Laid-Open No. 2014-33240, for example).

### SUMMARY

A solar cell module and a solar cell device are disclosed.

In one embodiment, a solar cell module includes a plurality of solar cell element groups, a light-transmitting substrate, a back-side protective member, a first sealing material, and a second sealing material. The solar cell element groups each include a plurality of solar cell elements and a wiring material. The solar cell elements are aligned in a first direction and each have a rectangular first surface and a rectangular second surface on the back side of the first surface. The wiring material electrically connects a first solar cell element and a second solar cell element belonging to the solar cell elements and being adjacent to each other in the first direction. The light-transmitting substrate is located to cover the solar cell element groups from a direction of the first surface. The back-side protective member is located to cover the solar cell element groups from a direction of the second surface. The first sealing material is located between the light-transmitting substrate and the solar cell element groups. The second sealing material is located between the solar cell element groups and the back-side protective member. The solar cell element groups are aligned in a second direction perpendicular to the first direction. Each of the solar cell elements includes four side parts connecting the first and second surfaces to each other. The four side parts include a first side part, a second side part on the back side of the first side part, a third side part, and a fourth side part on the back side of the third side part. Each of the third and fourth side parts is located along the first direction. Each of the first and second side parts is located along the second direction. The length of the first side part in the second direction and the length of the second side part in the second direction are larger than the length of the third side part in the first direction and the length of the fourth side part in the first direction. In each of the solar cell element groups, the solar cell elements are located in such a manner that the first side part and the second side part belonging to the solar cell elements face each other. The wiring material is electrically connected to the first surface of the first solar cell element along the first direction. The wiring material is electrically connected to the second surface of the second solar cell element along the first direction. The light-transmitting substrate has a first short side and a second short side each located along the first direction, and a first long side and a second long side each located along the second direction.

In one embodiment, the solar cell device includes the solar cell module according to the aforementioned embodiment, a first support member, and a second support member. The first support member is located at an end portion of the solar cell module along the first long side. The second support member is located at an end portion of the solar cell module along the second long side.

In one embodiment, a solar cell module includes a solar cell element group, a light-transmitting substrate, a back-side protective member, a first sealing material, and a second sealing material. The solar cell element group includes a first solar cell element, a second solar cell element, and a wiring material. The first and second solar cell elements are aligned in a first direction and each have a rectangular first surface and a rectangular second surface on the back side of the first surface. The wiring material electrically connects the first surface of the first solar cell element and the second surface of the second solar cell element. The light-transmitting substrate is located to cover the solar cell element group from a direction of the first surface. The back-side protective member is located to cover the solar cell element group from a direction of the second surface. The first sealing material is located between the light-transmitting substrate and the solar cell element group. The second sealing material is located between the solar cell element group and the back-side protective member. Each of the first and second solar cell elements includes a semiconductor substrate having a first substrate surface located on the first surface side, a second substrate surface located on the back side of the first substrate surface, a first side surface connecting the first and second substrate surfaces, and a second side surface located on the back side of the first side surface and connecting the first and second substrate surfaces. The first side surface of the first solar cell element is located to face the second side surface of the second solar cell element in the first direction. The second solar cell element includes an insulating layer covering the second side surface of the second solar cell element. The first side surface of the first solar cell element is exposed to the outside of the first solar cell element. In a region between the first side surface of the first solar cell element and the second side surface of the second solar cell element, the wiring material is located in a place closer to the second side surface of the second solar cell element than to the first side surface of the first solar cell element.

### BRIEF DESCRIPTION OF DRAWINGS

FIG. 1 is a plan view showing the structure of an example of a solar cell module;

FIG. 2 is a sectional view showing a cross section of the solar cell module taken along a line II-II of FIG. 1;

FIG. 3 is an enlarged view showing a place surrounded by a dashed line A3 of FIG. 2;

FIG. 4 is a plan view showing the structure of an example of a solar cell element viewed from a direction of a light-receiving surface;

FIG. 5 is a back view showing the structure of the example of the solar cell element viewed from a direction of a non-light-receiving surface;

FIG. 6 is a sectional view showing a cross section of the solar cell element taken along a line VI-VI of FIG. 4;

FIG. 7 is a sectional view showing a cross section of the solar cell element taken along a line VII-VII of FIG. 4;

FIG. 8 is a plan view showing the structure of an example of a master substrate for the solar cell element viewed from a direction of a light-receiving surface;

FIG. 9 is a back view showing the structure of the example of the master substrate for the solar cell element viewed from a direction of a non-light-receiving surface;

FIG. 10 shows a method of forming the solar cell element using the master substrate for the solar cell element and FIG. 10 is a sectional view showing a place corresponding to a cross section of the master substrate for the solar cell element taken along a line X-X of FIG. 8;

FIG. 11 shows the method of forming the solar cell element using the master substrate for the solar cell element and FIG. 11 is a sectional view showing a place corresponding to the cross section of the master substrate for the solar cell element taken along the line X-X of FIG. 8;

FIG. 12 shows an example of a laminator as a device for manufacturing the solar cell module and shows a state before the solar cell module is formed by application of pressure;

FIG. 13 shows an example of the laminator as a device for manufacturing the solar cell module and shows a state where the solar cell module is being formed by application of pressure;

FIG. 14 is a plan view showing the structure of an example of a solar cell device;

FIG. 15 is a sectional view showing a cross section of the solar cell device taken along a line XV-XV of FIG. 14;

FIG. 16 is a sectional view showing a cross section of the solar cell device taken along the line XV-XV of FIG. 14 in a state of application of a positive pressure load on the solar cell device;

FIG. 17 is a plan view showing a first solar cell module applied to a solar cell device according to Example;

FIG. 18 is a plan view showing a second solar cell module applied to a solar cell device according to Reference Example;

FIG. 19 shows a photograph obtained by shooting an image of EL (electroluminescence) generated in response to flow of a current in the first solar cell module of the solar cell device according to Example;

FIG. 20 shows a photograph obtained by shooting an image of EL (electroluminescence) generated in response to flow of a current in the second solar cell module of the solar cell device according to Reference Example;

FIG. 21 is a plan view showing the appearance of a solar cell element where a crack is developed in the first solar cell module applied to the solar cell device according to Example;

FIG. 22 is a plan view showing the appearance of a solar cell element where a crack is developed in the second solar cell module applied to the solar cell device according to Reference Example;

FIG. 23 shows an example of a solar cell module in a solar cell device according to a second embodiment and FIG. 23 is a sectional view showing a cross section of the solar cell module corresponding to a position taken along a line XXIII-XXIII of FIG. 1;

FIG. 24 shows an example of the solar cell module in the solar cell device according to the second embodiment and FIG. 24 is a sectional view showing a cross section of the solar cell module corresponding to a position taken along a line XXIV-XXIV of FIG. 1;

FIG. 25 shows an example of a solar cell module in a solar cell device according to a third embodiment and FIG. 25 is a sectional view showing a cross section of the solar cell module corresponding to a position taken along the line XXIII-XXIII of FIG. 1;

FIG. 26 shows an example of the solar cell module in the solar cell device according to the third embodiment and FIG. 26 is a sectional view showing a cross section of the solar cell module corresponding to a position taken along the line XXIV-XXIV of FIG. 1;

FIG. 27 is a sectional view showing a cross section of a solar cell module according to a fourth embodiment and FIG. 27 shows a place corresponding to the place surrounded by the dashed line A3 of FIG. 2;

FIG. 28 is a sectional view showing a cross section of a solar cell module according to a fifth embodiment and FIG. 28 shows a place corresponding to the place surrounded by the dashed line A3 of FIG. 2;

FIG. 29 is a plan view showing the structure of a solar cell device according to a sixth embodiment; and

FIG. 30 is a sectional view showing a cross section of the solar cell device taken along a line XXX-XXX of FIG. 29.

### DETAILED DESCRIPTION

### 1. Basic Technology

In a solar cell module, output may be increased by a way of connecting two divided solar cell elements in series, for example. This way can be achieved for example by making respective parting surfaces (cutting surfaces) of the two divided solar cell elements face each other and connecting the solar cell elements via a wiring material.

In a laminating step implemented for manufacturing such a solar cell module, however, pressing the wiring material strongly against the parting surface of the solar cell element causes risk of placing the parting surface and the wiring material close to each other, for example. If the wiring material comes too close to the parting surface of the solar cell element, for example, a current may leak from the parting surface into the wiring material to cause risk of output loss.

As another example, application of pressure responsive to wind, accumulated snow, etc. to a solar cell module installed in outdoor space may deflect the solar cell module. In this case, a crack may occur in a solar cell element. If a crack occurs in the solar cell element, for example, a region contributing to output may be reduced in the solar cell element to cause risk of output loss.

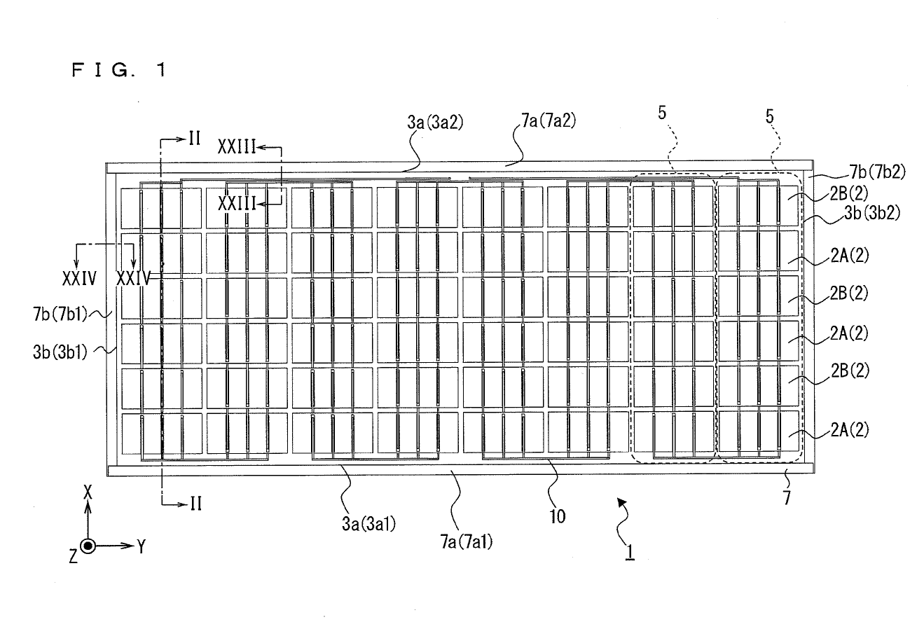

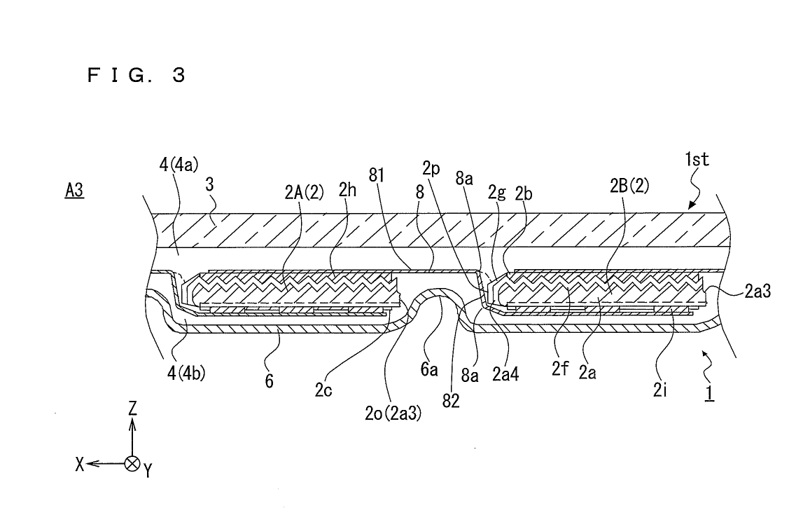

The present inventors have developed a technique that can reduce output loss in a high-output solar cell module. Various embodiments relating to this technique are described below based on the drawings. In the drawings, a common sign is assigned to comparable structures and to elements having the same function. In the description given below, these structures and elements will not be explained repeatedly. The drawings are given as schematic illustrations. FIGS. 1 to 30 are given a right-handed XYZ coordinate system according to which a direction (also called a first direction) corresponding to a direction of alignment of a plurality of solar cell elements 2 in a straight line forming a solar cell element group 5 (FIG. 1, etc.) is defined as a −X direction, a direction (also called a second direction) parallel to a first surface 2b (FIG. 3, etc.) as a light-receiving surface of the solar cell element 2 and perpendicular to the first direction is defined a +Y direction, and a direction perpendicular to the −X direction and the +Y direction is defined as a +Z direction.

### 2. First Embodiment

### 2-1. Solar Cell Module

A solar cell module 1 according to a first embodiment is described based on FIGS. 1 to 13.

As shown in FIGS. 1 to 3, the solar cell module 1 includes a light-transmitting substrate 3, a sealing material 4, a solar cell element group 5 including a plurality of solar cell elements 2, a sheet member 6 as a back-side protective member, and a frame 7. The sealing material 4 includes a first sealing material (also called a front-side sealing material) 4a arranged closer to the front surface of the solar cell module 1 and a second sealing material (also called a back-side sealing material) 4b arranged closer to the back surface of the solar cell module 1. The frame 7 includes members 7a forming long sides in a pair and members 7b forming short sides in a pair. The members 7a in a pair include a first member 7a1 and a second member 7a2. The members 7b in a pair include a third member 7b1 and a fourth member 7b2. The frame 7 is a squared frame formed by coupling the first, third, second, and fourth members 7a1, 7b1, 7a2, and 7b2 in this order into a ring shape.

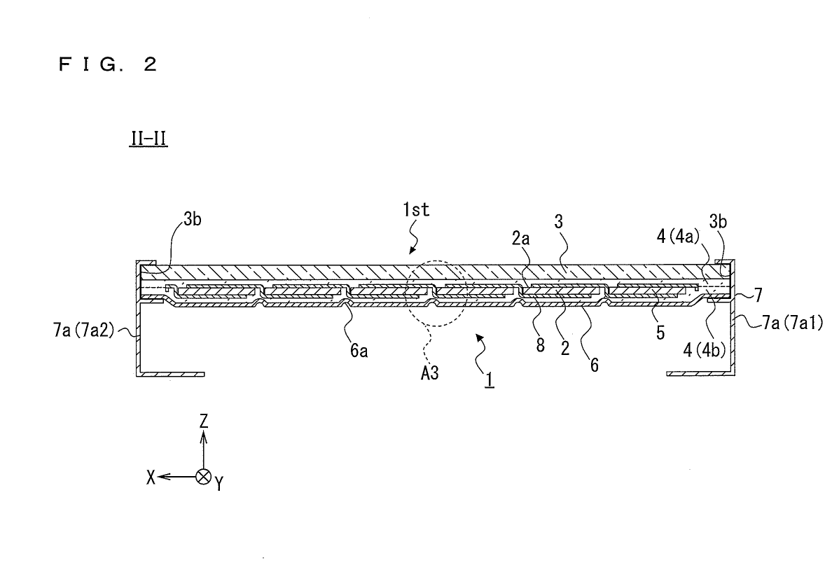

As shown in FIG. 2, in the solar cell module 1, the light-transmitting substrate 3, the front-side sealing material 4a, the solar cell element group 5, the back-side sealing material 4b, and the sheet member 6 are stacked in this order in a −Z direction. Specifically, a stack 1st including the light-transmitting substrate 3, the front-side sealing material 4a, the solar cell element group 5, the back-side sealing material 4b, and the sheet member 6 is formed. The solar cell element group 5 includes a plurality of solar cell elements 2 aligned in a straight line in the first direction (−X direction) and connected in series via a wiring material 8.

Each member of the solar cell module 1 is described next.

### 2-1-1. Solar Cell Element

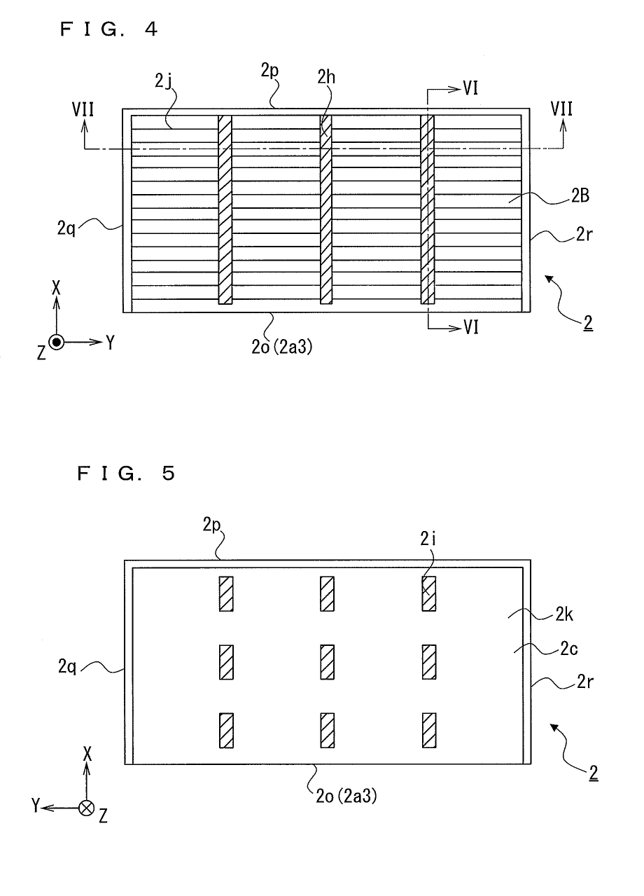

The solar cell element 2 has the function of converting solar light entering the solar cell element 2 to electricity. As shown in FIGS. 4 to 7, the solar cell element 2 has a first surface 2b and a second surface 2c on the back side of the first surface 2b. The solar cell element 2 includes a semiconductor substrate 2a having one conductivity type. The first surface 2b is arranged adjacent to a first surface (also called a first substrate surface) 2a1 of the semiconductor substrate 2a. The second surface 2c is arranged adjacent to a second surface (also called a second substrate surface) 2a2 of the semiconductor substrate 2a on the back side of the first substrate surface 2a1. The solar cell element 2 includes a front-side busbar electrode 2h and a finger electrode 2j located at the first surface 2b of the solar cell element 2. From a different viewpoint, the front-side busbar electrode 2h and the finger electrode 2j are arranged on the first substrate surface 2a1 of the semiconductor substrate 2a. The solar cell element 2 further includes a back-side busbar electrode 2i and a back electrode 2k located at the second surface 2c of the solar cell element 2. From a different viewpoint, the back-side busbar electrode 2i and the back electrode 2k are arranged on the second substrate surface 2a2 of the semiconductor substrate 2a. In this embodiment, the first surface 2b of the solar cell element 2 mainly functions as a light-receiving surface through which light is to enter the solar cell element 2.

For example, the first and second surfaces 2b and 2c of the solar cell element 2 each have a rectangular outer shape having long sides and short sides. Specifically, in a plan view of the solar cell element 2 taken from a direction of the first surface 2b, the solar cell element 2 has a rectangular outer shape having long sides and short sides. The short sides of the first surface 2b of the solar cell element 2 are practically parallel to the longitudinal direction of the front-side busbar electrode 2h. If the semiconductor substrate 2a is made of polycrystalline silicon, for example, the long sides of the solar cell element 2 can be set to range from about 120 to about 200 mm and the short sides of the solar cell element 2 can be set to range from about 60 to about 100 mm. In this specification, recitation “being practically parallel” is used to mean a form of being substantially parallel as well as a form of being completely parallel. Likewise, recitation “being practically vertical” is used to mean a form of being substantially vertical as well as a form of being completely vertical.

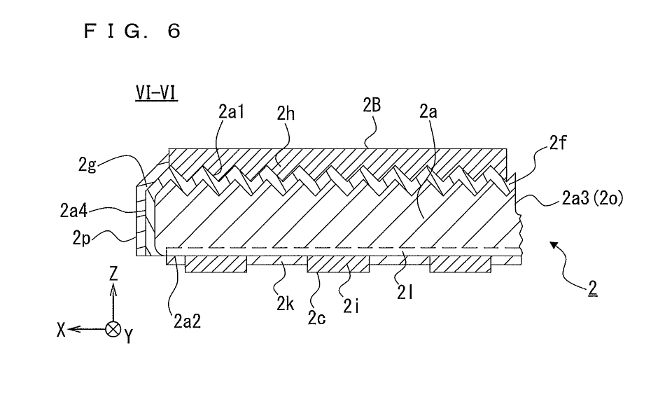

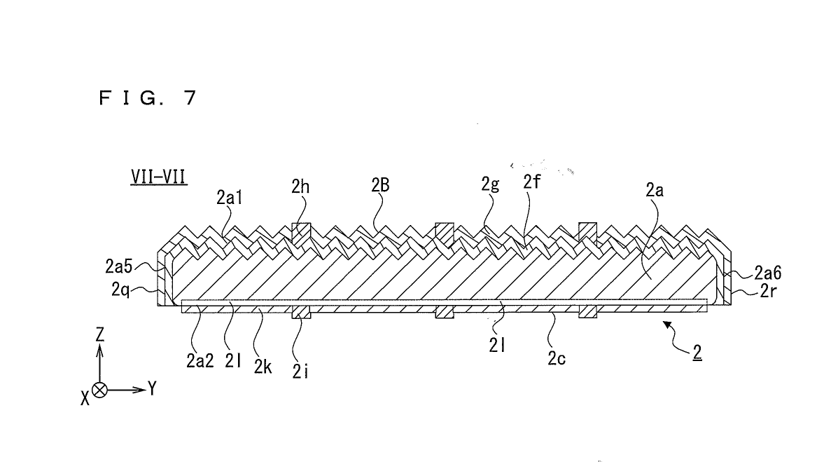

As shown in FIGS. 6 and 7, the solar cell element 2 includes an opposite conductivity type layer 2f and an insulating layer 2g arranged closer to the first substrate surface 2a1 of the semiconductor substrate 2a. The opposite conductivity type layer 2f has a conductivity type opposite to that of the semiconductor substrate 2a. The semiconductor substrate 2a has the first substrate surface 2a1 mainly corresponding to a surface through which light is to enter the solar cell element 2 and the second substrate surface 2a2 located on the back side of the first substrate surface 2a1. The opposite conductivity type layer 2f is provided adjacent to the first substrate surface 2a1 of the semiconductor substrate 2a. Specifically, the first substrate surface 2a1 is formed of the opposite conductivity type layer 2f. The insulating layer 2g is provided on the opposite conductivity type layer 2f adjacent to the first substrate surface 2a1 of the semiconductor substrate 2a.

The semiconductor substrate 2a has four side surfaces in addition to the first and second substrate surfaces 2a1 and 2a2. These four side surfaces include a first side surface 2a3, a second side surface 2a4, a third side surface 2a5, and a fourth side surface 2a6. The first side surface 2a3 connects the first and second substrate surfaces 2a1 and 2a2. The first side surface 2a3 extends along a long side of the first substrate surface 2a1. The second side surface 2a4 connects the first and second substrate surfaces 2a1 and 2a2 and is located on the opposite side (on the back side) of the first side surface 2a3. Thus, the second side surface 2a4 also extends along a long side of the first substrate surface 2a1. The third and fourth side surfaces 2a5 and 2a6 are side surfaces of the semiconductor substrate 2a except the first and second side surfaces 2a3 and 2a4 and extend practically perpendicularly to each of the first and second side surfaces 2a3 and 2a4. The first side surface 2a3 is a surface formed newly as a result of division of a master substrate 9 for solar cell elements described later.

The first surface 2b of the solar cell element 2 is formed of a surface of the front-side busbar electrode 2h, a surface of the finger electrode 2j, and a surface of the insulating layer 2g located adjacent to the first substrate surface 2a1. The second surface 2c of the solar cell element 2 is formed of a surface of the back-side busbar electrode 2i and a surface of the back electrode 2k.

Each structure of the solar cell element 2 is described in detail below.

A silicon substrate having one conductivity type (p-type, for example) given by adding a certain dopant element (impurity for conductivity type control) to the silicon substrate is used as the semiconductor substrate 2a. This silicon substrate to be used is a crystalline silicon substrate such as a monocrystalline silicon substrate or a polycrystalline silicon substrate, for example. In an example described below, a silicon substrate is used as the semiconductor substrate 2a. The thickness of the semiconductor substrate 2a can be set at 250 μm or less, and at 150 μm or less, for example. The first and second substrate surfaces 2a1 and 2a2 are rectangular. Thus, in a plan view of the semiconductor substrate 2a taken from a direction of the first substrate surface 2a1, the semiconductor substrate 2a has a rectangular outer shape. In this embodiment, a crystalline silicon substrate having a p-conductivity type is used as the semiconductor substrate 2a. By using boron or gallium as the dopant element, for example, the semiconductor substrate 2a fowled of the crystalline silicon substrate can be given a p-conductivity type. For example, the semiconductor substrate 2a can be formed as a crystalline silicon substrate like a thin plate by slicing a silicon ingot with a wire saw, etc. By immersing the semiconductor substrate 2a into an alkaline aqueous solution such as an aqueous solution of sodium hydroxide (NaOH) or potassium hydroxide (KOH), for example, a damaged layer, fine contaminated objects, etc. occurring during slicing process can be removed from the semiconductor substrate 2a. By being immersed into the alkaline aqueous solution, the semiconductor substrate 2a is dissolved in a range to a thickness from 10 to 15 μm from a surface. This chamfers a ridge portion formed between each of the second, third, and fourth side surfaces 2a4, 2a5, and 2a6 except the first side surface 2a3 resulting from division of the master substrate 9 for solar cell elements described later and each of the first and second substrate surfaces 2a1 and 2a2.

The opposite conductivity type layer 2f has a conductivity type opposite to that of the semiconductor substrate 2a. The opposite conductivity type layer 2f is formed as a front layer adjacent to the first substrate surface 2a1 of the semiconductor substrate 2a. If the semiconductor substrate 2a is a crystalline silicon substrate having a p-conductivity type, the opposite conductivity type layer 2f has an n-conductivity type. If the semiconductor substrate 2a is a crystalline silicon substrate having an n-conductivity type, the opposite conductivity type layer 2f has a p-conductivity type. A pn junction region is formed between a region of a p-conductivity type and a region of an n-conductivity type. If the semiconductor substrate 2a is a crystalline silicon substrate having a p-conductivity type, the opposite conductivity type layer 2f can be formed by diffusing impurity such as phosphorus in one surface of the crystalline silicon substrate that can become a light-receiving surface, for example. The opposite conductivity type layer 2f is only required to be provided on the first substrate surface 2a1 and is not required to be provided on the second, third, and fourth side surfaces 2a4, 2a5, and 2a6.

The insulating layer 2g is an insulating coating film provided on a plurality of surfaces of the semiconductor substrate 2a. If the insulating layer 2g is to be provided on the first substrate surface 2a1, the insulating layer 2g may have the function of increasing carriers in the solar cell element 2 resulting from photoexcitation responsive to received light by reducing the reflectivity of light in a desired wavelength region in the first substrate surface 2a1. By realizing this function, a photocurrent density Jsc in the solar cell element 2 can be increased. Examples of a film usable as the insulating layer 2g include a silicon nitride film, a titanium oxide film, and a silicon oxide film. Examples of process applicable for forming the insulating layer 2g include PECVD (plasma enhanced chemical vapor deposition) process, deposition process, and sputtering process. If the insulating layer 2g is to be formed by PECVD process using a silicon nitride film, for example, mixed gas of silane (SiH₄) and ammonia (NH₃) diluted with nitrogen (N₂) is introduced into a reaction chamber at about 500° C. Plasma of this mixed gas is produced by glow discharge decomposition and then deposited. In this way, the insulating layer 2g can be formed. The thickness of the insulating layer 2g can be determined appropriately in a manner that depends on its material. The insulating layer 2g can be set at a thickness that satisfies a condition for causing no reflection of proper incident light. For example, the refractive index of the insulating layer 2g can be set to range from about 1.8 to about 2.3 and the thickness of the insulating layer 2g can be set to range from about 50 to about 120 nm.

In the solar cell element 2, the second, third, and fourth side surfaces 2a4, 2a5, and 2a6 of the semiconductor substrate 2a are covered by the insulating layer 2g. Meanwhile, the first side surface 2a3 of the semiconductor substrate 2a is not covered by the insulating layer 2g. Specifically, the first side surface 2a3 of the semiconductor substrate 2a is a part exposed to the outside of the solar cell element 2 (this part is also called an exposed part). More specifically, a part made of semiconductor (in this embodiment, silicon) is exposed at the first side surface 2a3 of the semiconductor substrate 2a. “Exposing the semiconductor part” means a state of exposing the first side surface 2a3 of the semiconductor substrate 2a intentionally by not providing an insulating layer, etc. on purpose. Thus, the state of exposing the semiconductor substrate 2a includes a state where a natural oxide film is formed on the first side surface 2a3 of the semiconductor substrate 2a, for example. As another example, the state of exposing the semiconductor substrate 2a also includes a state where the opposite conductivity type layer 2f is partially formed on the first side surface 2a3 of the semiconductor substrate 2a.

For example, the insulating layer 2g can be formed by using PECVD process while the second, third, and fourth side surfaces 2a4, 2a5, and 2a6 of the semiconductor substrate 2a are not covered by any member.

In the description given below, an outermost layer of the solar cell element 2 adjacent to the first side surface 2a3 is defined as a first side part 2o, an outermost lost layer of the solar cell element 2 adjacent to the second side surface 2a4 is defined as a second side part 2p, an outermost layer of the solar cell element 2 adjacent to the third side surface 2a5 is defined as a third side part 2q, and an outermost layer of the solar cell element 2 adjacent to the fourth side surface 2a6 is defined as a fourth side part 2r. Specifically, the solar cell element 2 includes the first, second, third, and fourth side parts 2o, 2p, 2q, and 2r that form four side surface parts connecting the first and second surfaces 2b and 2c. Each of the first and second side parts 2o and 2p is located to extend in the second direction (+Y direction) and each of the third and fourth side parts 2q and 2r is located to extend in the first direction (−X direction). The length of each of the first and second side parts 2o and 2p in the second direction (+Y direction) is larger than that of each of the third and fourth side parts 2q and 2r in the first direction (−X direction). In this embodiment, the first side part 2o and the first side surface 2a3 mean the same part.

As shown in FIGS. 6 and 7, the solar cell element 2 includes a BSF region 21 formed at a superficial layer portion adjacent to the second substrate surface 2a2 of the semiconductor substrate 2a. The BSF region 21 (having a p+-type) contains the P-type dopant element of a concentration higher than an original concentration in the semiconductor substrate 2a. The BSF region 21 can form an internal electric field in a place adjacent to the second substrate surface 2a2 of the semiconductor substrate 2a. Thus, the BSF region 21 has the function of suppressing reduction in efficiency of photoelectric conversion by reducing the occurrence of recombination of carriers in a region near the second substrate surface 2a2 of the semiconductor substrate 2a.

In a plan view of the solar cell element 2 taken from a direction of the first substrate surface 2a1, the front-side busbar electrode 2h is a linear electrode located to extend in a direction perpendicular to the first and second side surfaces 2a3 and 2a4. In this plan view, the finger electrode 2j is a linear electrode located to extend in a direction parallel to the first and second side surfaces 2a3 and 2a4. The front-side busbar electrode 2h at least partially crosses the finger electrode 2j. The front-side busbar electrode 2h has a width from about 1.3 to about 2.5 mm, for example. The finger electrode 2j has a width from about 50 to about 200 μm, for example. Thus, the width of the finger electrode 2j is smaller than that of the front-side busbar electrode 2h. Here, a plurality of the finger electrodes 2j is provided in such a manner that the finger electrodes 2j are separated from each other at intervals from about 1.5 to about 3 mm. The respective thicknesses of the front-side busbar electrode 2h and the finger electrode 2j can be set to range from about 10 to about 40 μm. The front-side busbar electrode 2h and the finger electrode 2j can be formed by applying conductive paste mainly containing silver into an intended shape by screen printing, etc., and then by burning the conductive paste, for example.

In a perspective plan view of the semiconductor substrate 2a taken from a direction of the second substrate surface 2a2, the back-side busbar electrode 2i is provided in a position opposite the front-side busbar electrode 2h in the presence of the semiconductor substrate 2a between the back-side busbar electrode 2i and the front-side busbar electrode 2h. The back-side busbar electrode 2i is a linear electrode located to extend in a direction perpendicular to the first and second side surfaces 2a3 and 2a4. The form of the back-side busbar electrode 2i may be different from a succession of linear electrodes. As shown in FIG. 5, for example, the back-side busbar electrode 2i may be formed of a plurality of line segments. The back-side busbar electrode 2i has a thickness from about 10 to about 30 μm and a width from about 1.3 to about 7 mm, for example. The back-side busbar electrode 2i can be formed by using a material and a method comparable to those described above used for forming the front-side busbar electrode 2h. The back electrode 2k is formed at a practically entire surface adjacent to the second substrate surface 2a2 of the semiconductor substrate 2a except a partial region of the second substrate surface 2a2 of the semiconductor substrate 2a including a region where the back-side busbar electrode 2i is formed, for example. The thickness of the back electrode 2k may be set to range from about 15 to about 50 μm. The back electrode 2k can be formed by applying aluminum paste as conductive paste mainly containing aluminum into an intended shape and then by burning the conductive paste, for example.

Regarding the solar cell element 2 of this embodiment, a plurality of solar cell elements 2 can be formed by dividing the master substrate 9. The following explains a method of forming the solar cell elements 2 by dividing a large-scale solar cell element (in the below, the master substrate 9 for solar cell elements).

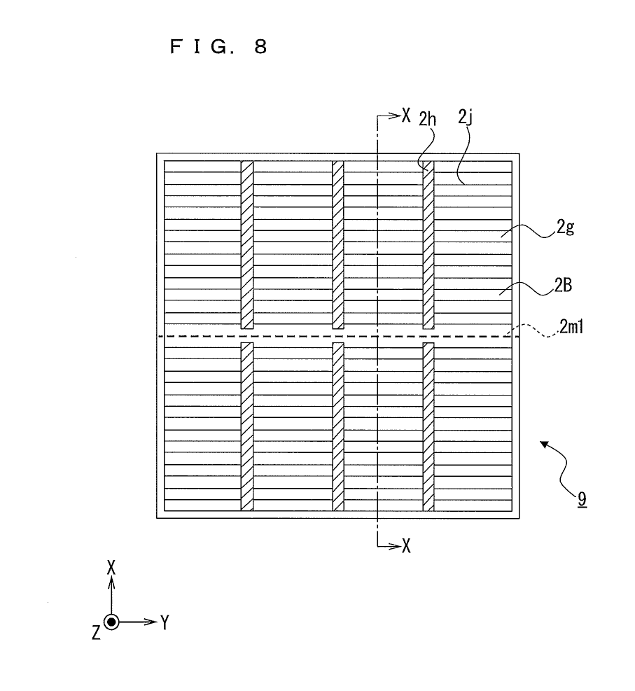

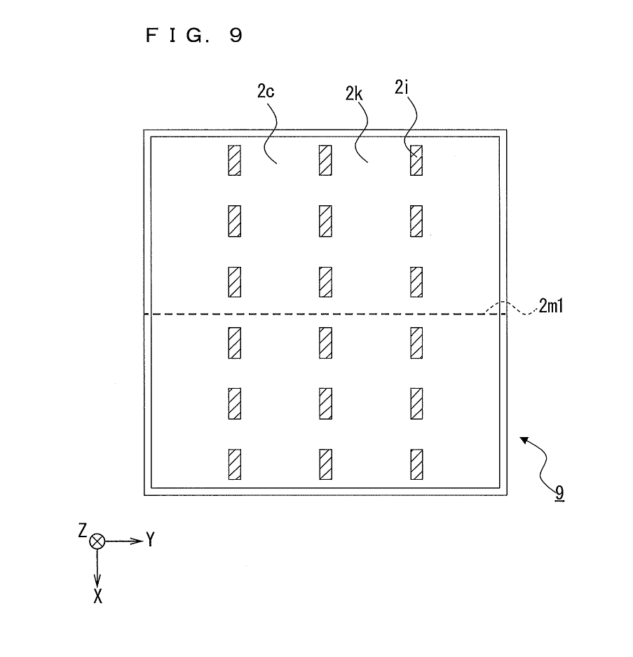

As shown in FIGS. 8 and 9, the master substrate 9 is a large-scale solar cell element before being divided into a plurality of solar cell elements 2. Thus, the master substrate 9 has a structure including the plurality of solar cell elements 2. As shown in FIGS. 8 and 9, for example, the master substrate 9 for solar cell elements includes the insulating layer 2g, the front-side busbar electrode 2h, the finger electrode 2j, the back-side busbar electrode 2i, and the back electrode 2k. Thus, the master substrate 9 is also usable as a solar cell element.

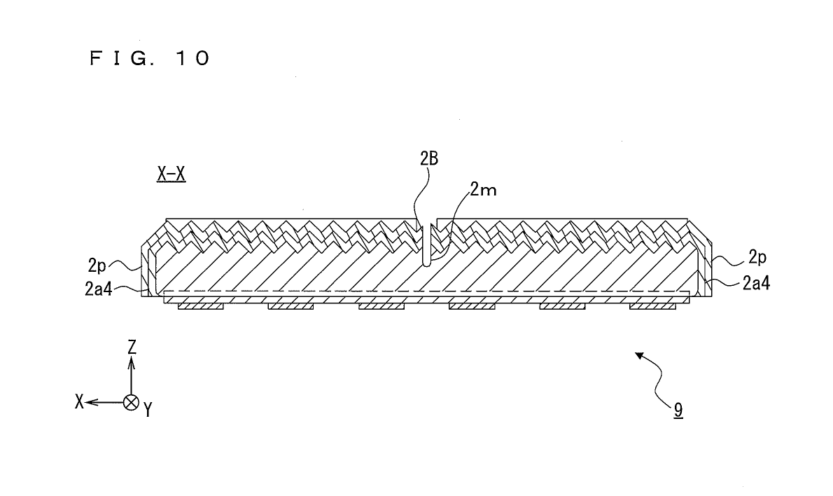

First, a region along a parting line indicated by a dashed line 2m1 in the first surface 2b of the master substrate 9 for solar cell elements is irradiated with laser light to form a parting groove 2m in the first surface 2b of the master substrate 9, as shown in FIG. 10. The laser light used herein may be YAG laser light, for example. Regarding conditions for the laser light, a wavelength may be set at 1.06 μm, output may be set to range from 10 to 30 W, a beam spread angle may be set to range from 1 to 5 mrad, and a scanning speed may be set to range from 50 to 300 mm/sec, for example. The depth of the parting groove 2m can be set at about 25% or more of the thickness of the semiconductor substrate 2a, for example. By doing so, the master substrate 9 for solar cell elements can be divided easily along the parting groove 2m.

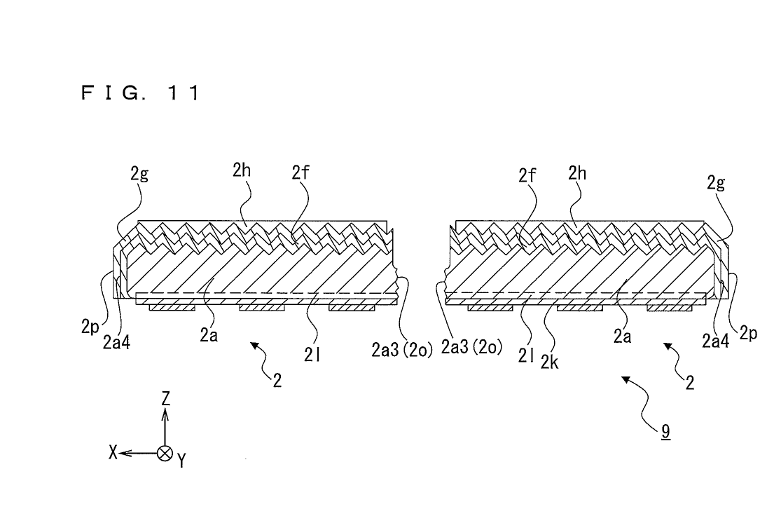

Next, external force is applied to the master substrate 9 in such a manner as to bend the master substrate 9 along the parting groove 2m, thereby dividing the master substrate 9 into two as shown in FIG. 11. In this way, two solar cell elements 2 can be formed. A surface (parting surface) formed by this dividing step becomes the first side part 2o where the first side surface 2a3 of the semiconductor substrate 2a is exposed.

The side parts of the solar cell element 2 except the first side part 2o become the second, third, and fourth side parts 2p, 2q, and 2r where the second, third, and fourth side surfaces 2a4, 2a5, and 2a6 of the semiconductor substrate 2a are covered by the insulating layer 2g respectively.

As shown in FIG. 6, in the solar cell element 2 formed by dividing the master substrate 9 in this way, the first side surface 2a3 including cross sections of the semiconductor substrate 2a, the opposite conductivity type layer 2f, the BSF region 21, the back electrode 2k. etc. is exposed at the first side part 2o. The insulating layer 2g is provided on the other side surfaces. Specifically, by using the aforementioned forming method, the solar cell element 2 can be formed including the first side part 2o where the first side surface 2a3 of the semiconductor substrate 2a is exposed and the second side part 2p where the second side surface 2a4 is covered by the insulating layer 2g.

<2-1-2. Light-Transmitting Substrate>

The light-transmitting substrate 3 is a member that protects the solar cell element 2. The light-transmitting substrate 3 is arranged to cover the solar cell element group 5 from a direction of the first surface 2b of the solar cell element 2. More specifically, the light-transmitting substrate 3 is arranged to cover the solar cell element group 5 from a direction of the first surface 2b in the presence of the front-side sealing material 4a between the light-transmitting substrate 3 and the solar cell element group 5. Specifically, the light-transmitting substrate 3 is arranged adjacent to the first surface 2b (adjacent to a light-receiving surface) of the solar cell element 2 through which light mainly enters the solar cell element 2. The light-transmitting substrate 3 may be a hard plate-like member that is required only to let light enter the solar cell element 2. A material for the light-transmitting substrate 3 is not particularly limited. For example, the light-transmitting substrate 3 can be made of a material having high light transmissivity. Examples of such a material include glass such as white sheet glass, tempered glass, and heat ray reflection glass of a thickness from about 2 to about 5 mm, and polycarbonate resin.

The light-transmitting substrate 3 has a rectangular front surface and a rectangular back surface each having long sides 3a in a pair located to extend in the second direction (+Y direction) and short sides 3b in a pair located to extend in the first direction (−X direction). The long sides 3a in a pair include a first long side 3a1 and a second long side 3a2. The short sides 3b in a pair include a first short side 3b1 and a second short side 3b2. Thus, as shown in FIG. 1, in a plan view of the solar cell module 1 taken from a direction of the first surface 2b, the outer shape of the solar cell module 1 is also rectangular.

The frame 7 is attached to surround the light-transmitting substrate 3. The frame 7 includes the members 7a forming long sides in a pair (more specifically, first and second members 7a1 and 7a2) and the members 7b forming short sides in a pair (more specifically, third and fourth members 7b1 and 7b2). To be specific, the members 7a are attached along corresponding ones of the long sides 3a and the members 7b are attached along corresponding ones of the short side 3b. To be more specific, the first member 7a1 is attached to the stack 1st along the first long side 3a1. The second member 7a2 is attached to the stack 1st along the second long side 3a2. The third member 7b1 is attached to the stack 1st along the first short side 3b1. The fourth member 7b2 is attached to the stack 1st along the second short side 3b2.

<2-1-3. Sealing Material>

The sealing material 4 is a member that can protect the Solar cell element 2 by sealing the solar cell element group 5. The front-side sealing material 4a is arranged between the light-transmitting substrate 3 and the solar cell element group 5. The back-side sealing material 4b is arranged between the solar cell element group 5 and the sheet member 6. For example, a material to be used as these sealing materials 4 may be a material mainly containing ethylene-vinyl acetate copolymer (EVA) or polyvinyl butyral (PVB) and formed into a sheet-like shape of a thickness from about 0.4 to about 1 mm by an extruder. The sealing material 4 may contain a cross-linking agent. In this case, the sealing material 4 can be formed by arranging the molded material formed into the sheet-like shape to become the sealing material in an intended position and then by curing the molded material by means of heat treatment thereon.

<2-1-4. Sheet Member>

The sheet member 6 has the function of protecting the back-side sealing material 4b. The sheet member 6 is arranged to cover the solar cell element group 5 from a direction of the second surface 2c of the solar cell element 2. More specifically, the sheet member 6 is arranged to cover the solar cell element group 5 from a direction of the second surface 2c in the presence of the back-side sealing material 4b between the sheet member 6 and the solar cell element group 5. For example, the sheet member 6 is thinner than the light-transmitting substrate 3 and has a lower modulus of elasticity than the light-transmitting substrate 3. For example, a sheet of soft resin such as polyvinyl fluoride (PVF), polyethylene terephthalate (PET), or polyethylene naphthalate (PEN), or a sheet having a stack of two or more of these resins is applicable as a material for the sheet member 6.

<2-1-5. Wiring Material>

The wiring material 8 is band-shaped conductive metal, for example. For example, a material applicable as the wiring material 8 may be copper foil having a thickness from about 0.1 to about 0.2 mm and a width from about 1 to 2 mm while being entirely coated with solder.

<2-1-6. Solar Cell Element Group>

The solar cell element group 5 includes a plurality of solar cell elements 2 aligned in the first direction (−X direction) and the wiring material 8 connecting adjacent ones of the solar cell elements 2 in series.

One of adjacent solar cell elements 2 in a pair belonging to the solar cell element group 5 is called a first solar cell element 2A and the other of these solar cell elements 2 is called a second solar cell element 2B, for example. In the solar cell element group 5, the first and second solar cell elements 2A and 2B are aligned alternately in the first direction (−X direction). The first and second solar cell elements 2A and 2B can be formed by dividing one master substrate 9 shown in FIGS. 8 and 9, for example. Specifically, the first and second solar cell elements 2A and 2B correspond to the solar cell elements 2 shown in FIG. 11 obtained by dividing the master substrate 9 into two.

In the illustrations of FIGS. 2 and 3, in one solar cell element group 5, six solar cell elements 2 are aligned in the first direction (−X direction) and connected in series. Here, the first to sixth solar cell elements 2 aligned in the first direction (−X direction) include odd-numbered solar cell elements 2 each called the first solar cell element 2A and even-numbered solar cell elements 2 each called the second solar cell element 2B.

Here, M is assumed to be a natural number from 1 to 3, for example. In this case, the first solar cell element 2A as a (2M−1)^{th} solar cell element 2 and the second solar cell element 2B as a 2M^{th} solar cell element 2 are connected in series via the wiring material 8 as follows. The first and second solar cell elements 2A and 2B are arranged in such a manner that the first side surface 2a3 of the first solar cell element 2A and the second side surface 2a4 of the second solar cell element 2B face each other. Specifically, the first and second solar cell elements 2A and 2B are arranged in such a manner that the first side part 2o of the first solar cell element 2A and the second side part 2p of the second solar cell element 2B face each other. The wiring material 8 is arranged to extend in such a manner that its longitudinal direction agrees with the direction in which the first and second solar cell elements 2A and 2B are aligned alternately. One end portion of the wiring material 8 is soldered to the first surface 2b (a surface of the front-side busbar electrode 2h) of the first solar cell element 2A. An opposite end portion of the wiring material 8 is soldered to the second surface 2c (a surface of the back-side busbar electrode 2i) of the second solar cell element 2B. Specifically, the wiring material 8 electrically connects the first surface 2b of the first solar cell element 2A and the second surface 2c of the second solar cell element 2B in series. More specifically, a section of the wiring material 8 on its one end portion side is soldered to the surface of the front-side busbar electrode 2h along the longitudinal direction of this front-side busbar electrode 2h, for example. A section of the wiring material 8 on its opposite end portion side is soldered to the surface of the back-side busbar electrode 2i along the longitudinal direction of this back-side busbar electrode 2i, for example. Specifically, the wiring material 8 is electrically connected to the first surface 2b of the first solar cell element 2A along the first direction (−X direction) and is electrically connected to the second surface 2c of the second solar cell element 2B along the first direction (−X direction). In this way, electrical connection is formed via the wiring material 8 between the first surface 2b of the first solar cell element 2A as the (2M−1)^{th} solar cell element 2 and the second surface 2c of the second solar cell element 2B as the 2M^{th} solar cell element 2 adjacent to this first solar cell element 2A.

As another example, N is assumed to be a natural number from 1 to 2. In this case, the second solar cell element 2B as a 2N^{th} solar cell element 2 and the first solar cell element 2A as a (2N+1)^{th} solar cell element 2 are connected in series via the wiring material as follows. One end portion of the wiring material 8 is soldered to the first surface 2b (a surface of the front-side busbar electrode 2h) of the second solar cell element 2B. An opposite end portion of the wiring material 8 is soldered to the second surface 2c (a surface of the back-side busbar electrode 2i) of the first solar cell element 2A. More specifically, a section of the wiring material 8 on its one end portion side is soldered to the surface of the front-side busbar electrode 2h along the longitudinal direction of this front-side busbar electrode 2h, for example. A section of the wiring material 8 on its opposite end portion side is soldered to the surface of the back-side busbar electrode 2i along the longitudinal direction of this back-side busbar electrode 2i, for example. In this way, electrical connection is formed via the wiring material 8 between the first surface 2b of the second solar cell element 2B as the 2N^{th} solar cell element 2 and the second surface 2c of the first solar cell element 2A as the (2N+1)^{th} solar cell element 2 adjacent to this second solar cell element 2B.

In this embodiment, the solar cell module 1 includes the solar cell element group 5 including arrangement of electrodes electrically connected in the aforementioned manner. Thus, as shown in FIGS. 1 to 3, in a plan view of the solar cell element group 5 taken from a direction of the first surface 2b, the wiring material 8 is arranged to extend perpendicularly to the first side surface 2a3 of the first solar cell element 2A and the second side surface 2a4 of the second solar cell element 2B and practically parallel to the third and fourth side surfaces 2a5 and 2a6.

As shown in FIGS. 1 to 3, the solar cell module 1 includes a plurality of solar cell element groups 5 aligned in the second direction (+Y direction) perpendicular to the first direction (−X direction) corresponding to the longitudinal direction of the solar cell element group 5. Solar cell element groups 5 adjacent to each other in the second direction are electrically connected to each other via a connection member 10. The connection member 10 can be made of a material comparable to that used for forming the wiring material 8.

### 2-2. Method of Manufacturing Solar Cell Module

A method of manufacturing the solar cell module 1 is described next.

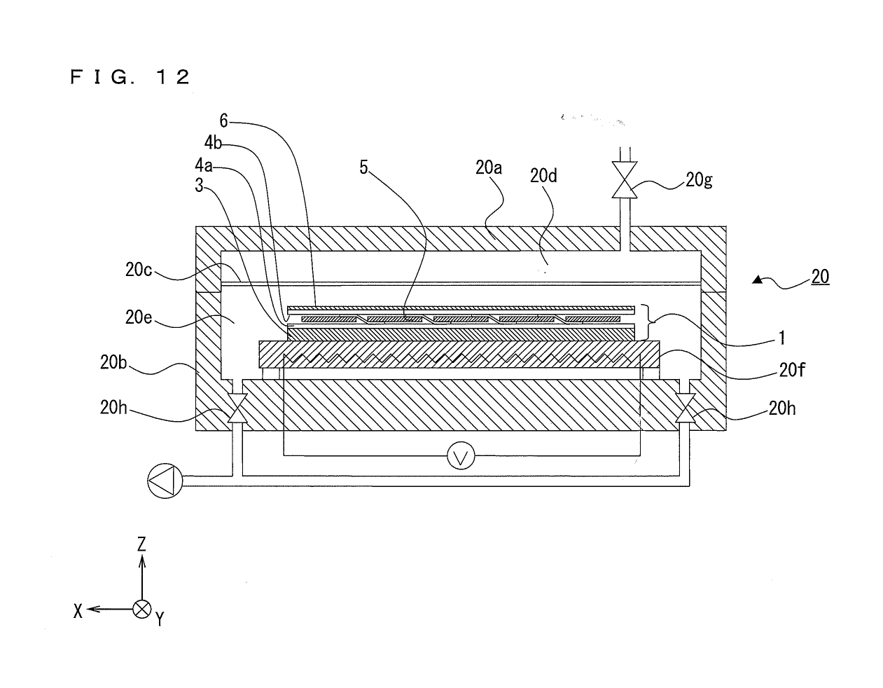

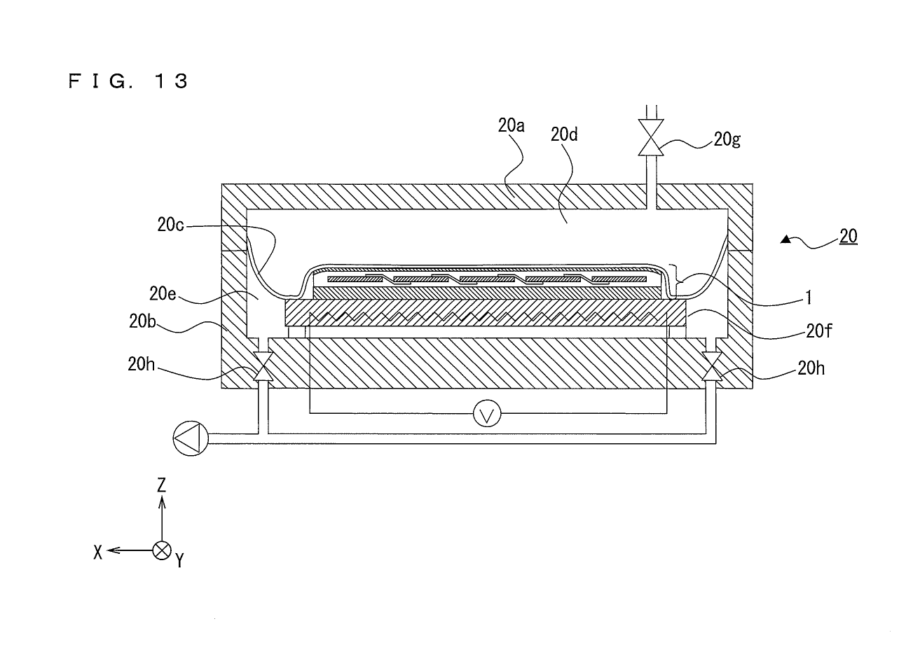

The solar cell module 1 can be manufactured by integrating the light-transmitting substrate 3, the front-side sealing material 4a, a plurality of solar cell element groups 5, the back-side sealing material 4b, and the sheet member 6 using a laminating machine (laminator). A laminating step implemented by using a laminator 20 is described next using FIGS. 12 and 13.

The laminator 20 includes a housing including an upper housing 20a and a lower housing 20b that are related to each other in such a manner as to permit opening and closing of the housing. The inside of the hosing is separated by a diaphragm sheet 20c into an upper vacuum region 20d and a lower vacuum region 20e. A heater board 20f is arranged in a substantially central area of the inside of the lower housing 20b.

The upper housing 20a is connected to an upper vacuum pump 20g configured to allow pressure reduction in the upper vacuum region 20d surrounded by the diaphragm sheet 20c and the upper housing 20a. The lower housing 20b is connected to a lower vacuum pump 20h for pressure reduction in the lower vacuum region 20e. A resin member having sufficient strength and sufficient stretching properties such as silicon rubber is used as the diaphragm sheet 20c.

In the laminator 20, a stack is formed by stacking the light-transmitting substrate 3, the front-side sealing material 4a, a plurality of solar cell element groups 5, the back-side sealing material 4b, and the sheet member 6 in this order. While pressure inside the housing is reduced to from about 50 to about 150 Pa, this stack is pressurized while being heated to a temperature from about 100 to about 200° C. for a length of time from about 15 to about 60 minutes. This fuses the front-side sealing material 4a and the back-side sealing material 4b to integrate the stack. More specifically, in the laminator 20, while the stack is heated while being arranged on the heater board 20f in such a manner that the light-transmitting substrate 3 contacts the heater board 20f, pressure inside the housing is reduced using the upper vacuum pump 20g and the lower vacuum pump 20h and then air pressure in the upper vacuum region 20d is increased to a level higher than that in the lower vacuum region 20e. This makes the diaphragm sheet 20c apply pressure to the stack from a direction of the sheet member 6, thereby integrating the stack.

As shown in FIG. 2, in the solar cell module 1 manufactured by the aforementioned laminating step, the sheet member 6 has recesses and projections formed in such a manner as to emerge the shape of the solar cell element 2 and that of the wiring material 8. In particular, as shown in FIG. 3, the sheet member 6 has a recess 6a between the first and second solar cell elements 2A and 2B that is hollowed toward the light-transmitting substrate 3. Thus, the wiring material 8 connected to the back-side busbar electrode 2i of the second solar cell element 2B includes bent parts 8a in two positions that make the wiring material 8 extend along a ridge portion formed between the second surface 2c and the second side part 2p of the second solar cell element 2B. Meanwhile, the wiring material 8 connected to the front-side busbar electrode 2h of the first solar cell element 2A is not bent at a ridge portion between the first surface 2b and the first side part 2o (first side surface 2a3) of the first solar cell element 2A but it is located to extend along a surface of the light-transmitting substrate 3 adjacent to the solar cell element group 5 toward the second solar cell element 2B.

For example, the two bent parts 8a of the wiring material 8 are located closer to the second side surface 2a4 of the semiconductor substrate 2a of the second solar cell element 2B than to the first side surface 2a3 of the semiconductor substrate 2a of the first solar cell element 2A. For example, a part of the wiring material 8 between the two bent parts 8a is arranged in the vicinity of the second side surface 2a4 of the second solar cell element 2B and closer to the second side surface 2a4 of the semiconductor substrate 2a of the second solar cell element 2B than to the first side surface 2a3 of the semiconductor substrate 2a of the first solar cell element 2A. Specifically, in a region between the first side surface 2a3 (first side part 2o) of the first solar cell element 2A and the second side part 2p of the second solar cell element 2B, the wiring material 8 is located in a place closer to the second side part 2p of the second solar cell element 2B than to the first side surface 2a3 (first side part 2o) of the first solar cell element 2A. Additionally, the thickness of the insulating layer 2g covering the second side part 2p is small. Thus, in a region between the first side surface 2a3 of the first solar cell element 2A and the second side surface 2a4 of the second solar cell element 2B, the wiring material 8 is located in a place closer to the second side surface 2a4 of the second solar cell element 2B than to the first side surface 2a3 (first side part 2o) of the first solar cell element 2A. This makes it unlikely that the wiring material 8 will contact the first side surface 2a3.

From a different viewpoint, the wiring material 8 includes a first part 81 located to extend from a direction of the first surface 2b of the first solar cell element 2A along the first direction (−X direction) to approach the first surface 2b of the second solar cell element 2B. The wiring material 8 includes a second part 82 located to extend from a direction of the light-transmitting substrate 3 toward the sheet member 6. The wiring material 8 includes the bent part (also called a first bent part) 8a connecting the first and second parts 81 and 82 while being located in a position closer to the second side surface 2a4 of the second solar cell element 2B than to the first side surface 2a3 of the first solar cell element 2A.

For example, one of the two bent parts 8a of the wiring material 8 closer to the light-transmitting substrate 3 is located at a boundary between the front-side sealing material 4a contacting the light-transmitting substrate 3 and the back-side sealing material 4b contacting the sheet member 6. One of the two bent parts 8a of the wiring material 8 closer to the sheet member 6 is arranged in the back-side sealing material 4b. A radius of curvature of the wiring material 8 at the bent parts 8a can be adjusted properly. Specifically, the wiring material 8 may be curved at the bent parts 8a smoothly, not steeply.

### 2-3. Characteristics of Solar Cell Module

In this embodiment, the insulating layer 2g is provided on the second side surface 2a4 of the semiconductor substrate 2a on the second side part 2p side of the second solar cell element 2B. Thus, even if the wiring material 8 is located to be close to the second side surface 2a4 of the semiconductor substrate 2a of the second solar cell element 2B, the wiring material 8 and the second side surface 2a4 of the semiconductor substrate 2a of the second solar cell element 2B are still unlikely to contact each other directly. This can reduce the occurrence of leakage current due to contact of the wiring material 8 with the semiconductor substrate 2a of the solar cell element 2B, for example. As a result, output loss of the solar cell module 1 can be reduced.

In this embodiment, the insulating layer 2g is not provided so the first side surface 2a3 of the semiconductor substrate 2a is exposed at the first side part 2o of the first solar cell element 2A. Meanwhile, the first side surface 2a3 of the first solar cell element 2A and the wiring material 8 are separated from each other. This makes it unlikely that the first side surface 2a3 of the first solar cell element 2A and the wiring material 8 contact each other. Thus, while the semiconductor substrate 2a is exposed at the first side part 2o of the first solar cell element 2A, leakage current is unlikely to occur between the first side part 2o and the wiring material 8. Further, by the presence of the sealing material 4 having insulating properties entering a gap between the first side part 2o of the first solar cell element 2A and the wiring material 8, insulation between the first side part 2o of the first solar cell element 2A and the wiring material 8 can be ensured more reliably.

As described above, in this embodiment, the high-output solar cell module 1 of low output loss can be formed using the solar cell elements 2 (first and second solar cell elements 2A and 2B) that can be easily obtained by dividing the master substrate 9. Specifically, in this embodiment, even if there is a part not provided with the insulating layer 2g in the respective side surfaces of the first and second solar cell elements 2A and 2B facing each other, the occurrence of leakage current can still be reduced.

In this embodiment, on the second solar cell element 2B side, for example, the wiring material 8 is located to be close to a ridge portion formed of the first surface 2b, the second side part 2p, and the second surface 2c of the semiconductor substrate 2a. Hence, the wiring material 8 may contact this ridge portion of the semiconductor substrate 2a in the laminating step to cause risk of application of pressure to the ridge portion. In this regard, as a result of the aforementioned process of immersing the semiconductor substrate 2a in the alkaline aqueous solution, the ridge portion of the semiconductor substrate 2a formed of the first substrate surface 2a1, the second substrate surface 2a2, and the second side surface 2a4 is smoothened. Thus, application of pressure on the ridge portion by the wiring material 8 is not likely to cause a flaw such as a crack in the semiconductor substrate 2a. Meanwhile, the first side part 2o of the first solar cell element 2A is a fracture surface resulting from division of the master substrate 9. Such a fracture surface has fine irregularities, scratches, etc. occurring during the division. Hence, the first side part 2o of the first solar cell element 2A is likely to become a starting point for a crack. In this regard, according to the structure of this embodiment, the wiring material 8 is unlikely to contact the first side part 2o of the first solar cell element 2A. Thus, a crack is unlikely to develop. This can reduce output loss of the solar cell element 2 due to expansion of a crack, for example.

### 2-4. Solar Cell Device

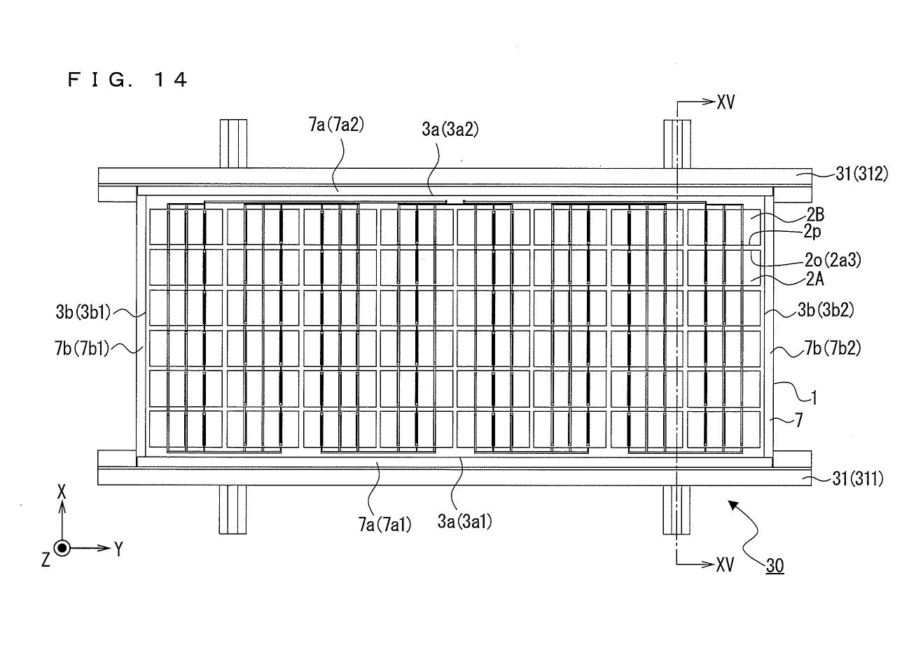

As shown in FIGS. 14 to 16, a solar cell device 30 according to the first embodiment includes the solar cell module 1 and a support member 31 that supports the solar cell module 1 from below.

In the solar cell device 30, the solar cell element group 5 is arranged in such a manner that the long side (first side part 2o) of the first solar cell element 2A and the long side (second side part 2p) of the second solar cell element 2B extend along the second direction (+Y direction) perpendicular to the first direction (−X direction). In the solar cell device 30, the solar cell module 1 includes the light-transmitting substrate 3 having a rectangular front surface and a rectangular back surface. The long sides 3a in a pair of the light-transmitting substrate 3 each extend in the second direction (+Y direction). The short sides 3b in a pair of the light-transmitting substrate 3 each extend in the first direction (−X direction). The frame 7 is arranged around the solar cell module 1. The frame 7 is formed of the first and second members 7a1 and 7a2 attached to portions of the light-transmitting substrate 3 extending along corresponding ones of the long sides 3a in a pair, and the third and fourth members 7b1 and 7b2 attached to portions of the light-transmitting substrate 3 extending along corresponding ones of the short sides 3b in a pair.

The support member 31 is a member that supports the solar cell module 1. The support member 31 has a longitudinal direction along the second direction (+Y direction) in which the first and second members 7a1 and 7a2 of the frame 7 extend. The support member 31 is an elongated member (also called a horizontal member) longer in the second direction (+Y direction) than the first and second members 7a1 and 7a2 and the long sides 3a in a pair. The support member 31 supports the solar cell module 1 from below by contacting the lower surface of the frame 7. More specifically, the solar cell device 30 includes a support member 31 (also called a first support member 311) arranged to support the first member 7a1 extending along the first long side 3a1 of the solar cell module 1, and a support member 31 (also called a second support member 312) arranged to support the second member 7a2 extending along the second long side 3a2 of the solar cell module 1. The first support member 311 supports the first member 7a1 from below along the longitudinal direction of the first member 7a1. The second support member 312 supports the second member 7a2 from below along the longitudinal direction of the second member 7a2. More specifically, while the first member 7a1 contacts the first support member 311 along the longitudinal direction of the first member 7a1, the first member 7a1 can be attached to the first support member 311 by means including fitting, engagement, insertion, and coupling using fixation with a screw, for example.

In the solar cell device 30 according to this embodiment, each of the third and fourth members 7b1 and 7b2 of the frame 7 arranged to extend along the short side of the solar cell module 1 is not supported by the support member 31 except the opposite ends of each of the third and fourth members 7b 1 and 7b2.

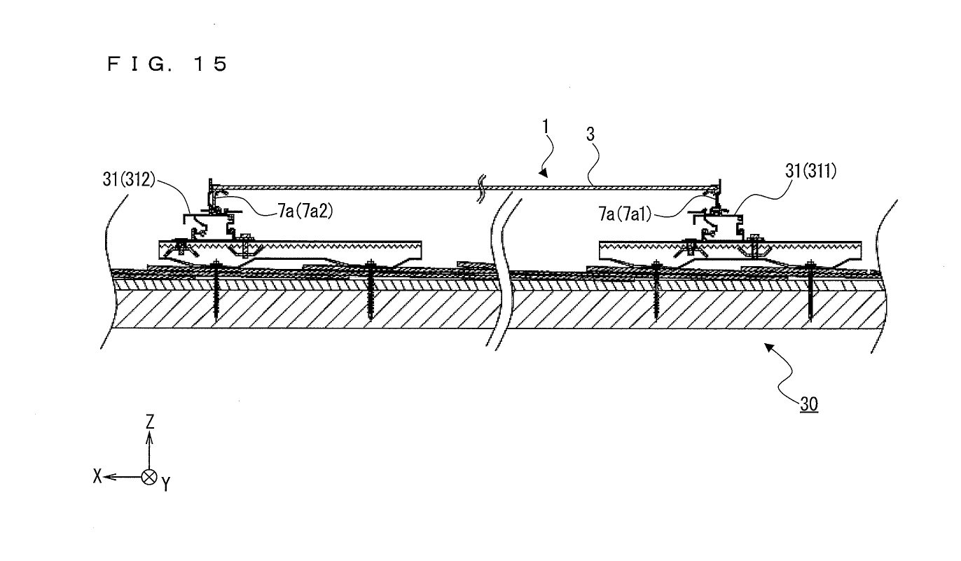

In the solar cell device 30, by accumulated snow or wind pressure, for example, a load (positive pressure load) pressing the solar cell module 1 from a direction of the light-transmitting substrate 3 or a load (negative pressure load) pressing the solar cell module 1 from a direction of the sheet member 6 may be applied to the solar cell module 1. The third and fourth members 7b1 and 7b2 extending along the short sides of the solar cell module 1 are not supported by the support member 31. Thus, during application of such a load, the solar cell module 1 is curved in a direction that agrees with the short direction of the solar cell element 2 (a direction in which the third and fourth side parts 2q and 2r extend), as shown in FIG. 16. Specifically, the third and fourth side parts 2q and 2r may be curved.

However, the third and fourth side parts 2q and 2r forming the short sides in a pair of the solar cell element 2 are shorter than the first and second side parts 2o and 2p forming the long sides in a pair of the solar cell element 2. Thus, if stress is applied to the solar cell module 1 in such a manner that the solar cell module 1 is curved in a direction along the short sides of the solar cell element 2, the solar cell element 2 is less likely to be curved than in the case where stress is applied to the solar cell module 1 in such a manner that the solar cell module 1 is curved in a direction along the long sides of the solar cell element 2. This produces what is called size effect in this embodiment, so that the occurrence of a crack can be reduced, compared to the case where the solar cell module 1 is curved in a direction along the second direction (+Y direction). Further, one of the long sides in a pair of the solar cell element 2 is a side resulting from the dividing step implemented by laser irradiation or bending. By contrast, the short sides in a pair of the solar cell element 2 are sides having no history of exposure to processing. Thus, irregularities that might result in stress concentration occur less seriously in the short sides than in the long sides of the solar cell element 2. This also shows that the occurrence of a crack in the solar cell element 2 can be reduced in the case where stress is applied to the solar cell module 1 in such a manner that the solar cell module 1 is curved in a direction along the short sides of the solar cell element 2, compared to the case where stress is applied to the solar cell module 1 in such a manner that the solar cell module 1 is curved in a direction along the long sides of the solar cell element 2.

### 2-5. Example

Example of this embodiment is described next.

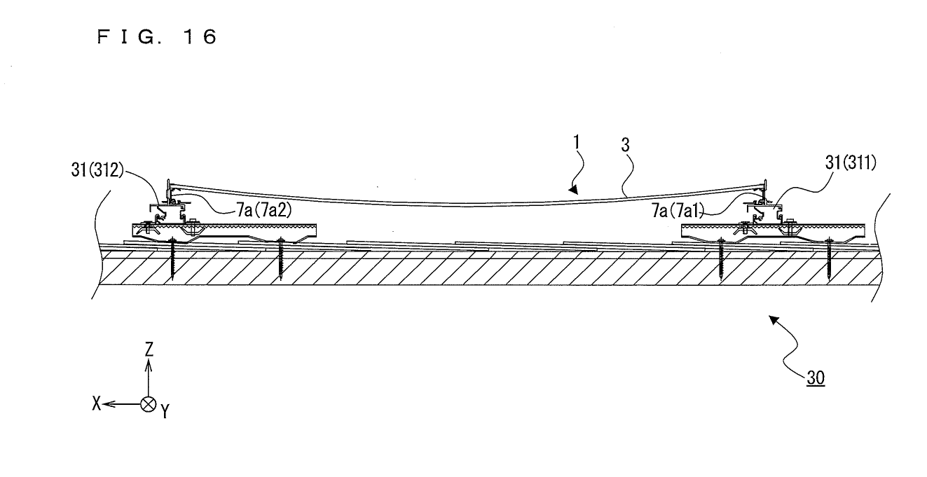

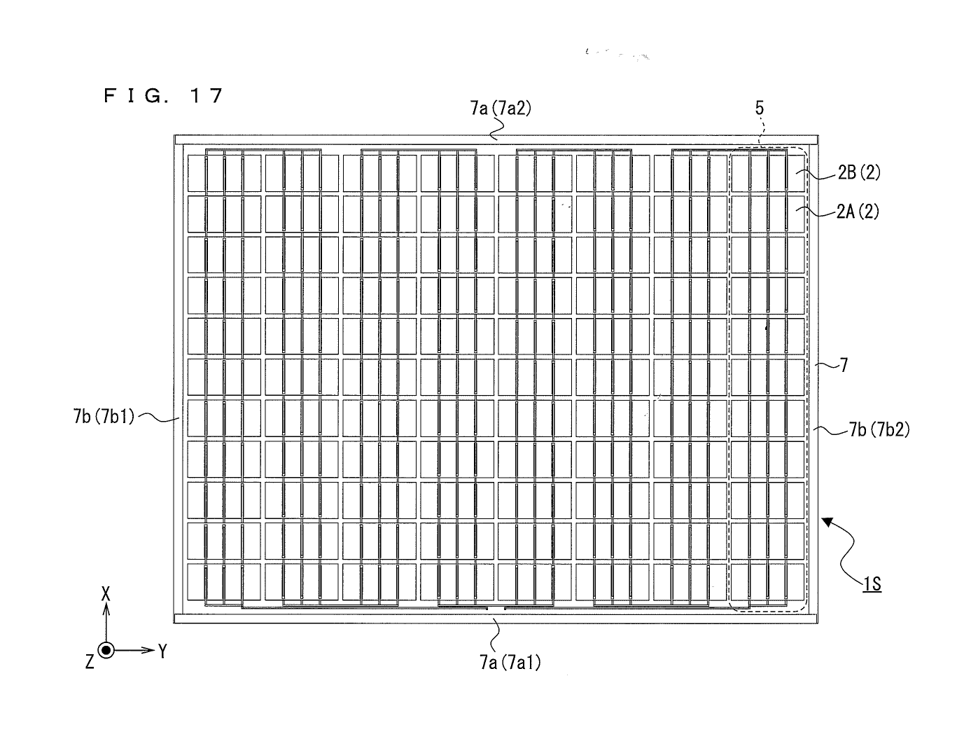

A first solar cell module 1S was prepared as a solar cell module in the solar cell device 30 according to Example of this embodiment. As shown in FIG. 17, the first solar cell module 1S includes the solar cell elements 2 arranged in a matrix of 11 rows in the first direction (−X direction) and 8 columns in the second direction (+Y direction) in such a manner that the longitudinal direction of the solar cell element group 5 (first direction) extends along the short sides 3b in a pair of the first solar cell module 1S. The first and second surfaces 2b and 2c of each solar cell element 2 were each formed into a rectangle having a transversal length of 156 mm and a vertical length of 78 mm. The first solar cell module 15 has a length of 1305 mm measured along the members 7a forming the long sides in a pair of the frame 7 and a length of 915 mm measured along the members 7b forming the short sides in a pair of the frame 7.

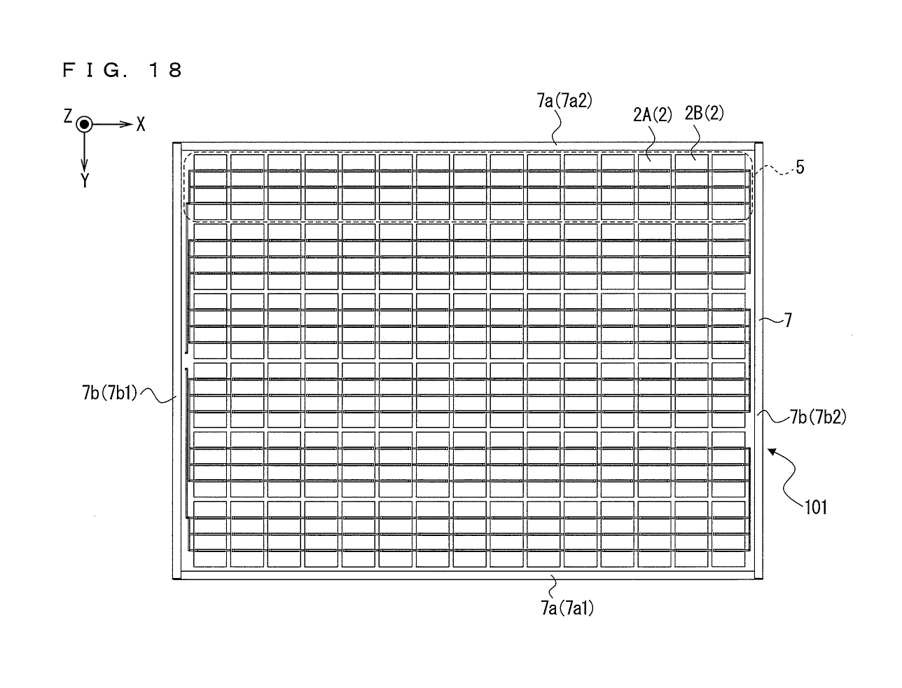

A second solar cell module 101 was prepared as a solar cell module in a solar cell device according to Reference Example. As shown in FIG. 18, the second solar cell module 101 includes the solar cell elements 2 arranged in a matrix of 15 columns in the first direction (−X direction) and 6 rows in the second direction (+Y direction) in such a manner that the longitudinal direction of the solar cell element group 5 (first direction) extends along long sides in a pair of the second solar cell module 101. The front and back surfaces of each solar cell element 2 were each formed into a rectangle having a vertical length of 156 mm and a transversal length of 78 mm. The second solar cell module 101 has a length of 1245 mm measured along the members 7a forming the long sides of the frame 7 and a length of 970 mm measured along the members 7b forming the short sides in a pair of the frame 7.

Next, in each of the first and second solar cell modules 1S and 101, the members 7a in a pair forming the long sides of the frame 7 were supported from below by the support member 31. In this way, the solar cell devices were completed. Then, a positive pressure load and a negative pressure load of 2500 Pa were applied to each of the first and second solar cell modules 1S and 101. The positive pressure load was applied by exposing each of the first and second solar cell modules 1S and 101 to wind from a direction of the light-transmitting substrate 3. The negative pressure load was applied by exposing each of the first and second solar cell modules 15 and 101 to wind from a direction of the sheet member 6. Next, using each of the first and second solar cell modules 15 and 101 as a target, a current was flown using the wiring material 8 and an image of a distribution of light emission (electroluminescence) resulting from the current flow was formed by image shooting using an infrared camera. Based on this distribution, determinations were made about the presence or absence of the occurrence of a crack, the presence or absence of regions disconnected from electrical connection via the wiring material 8, and the presence or absence of a crack occurrence resulting in the occurrence of such regions.

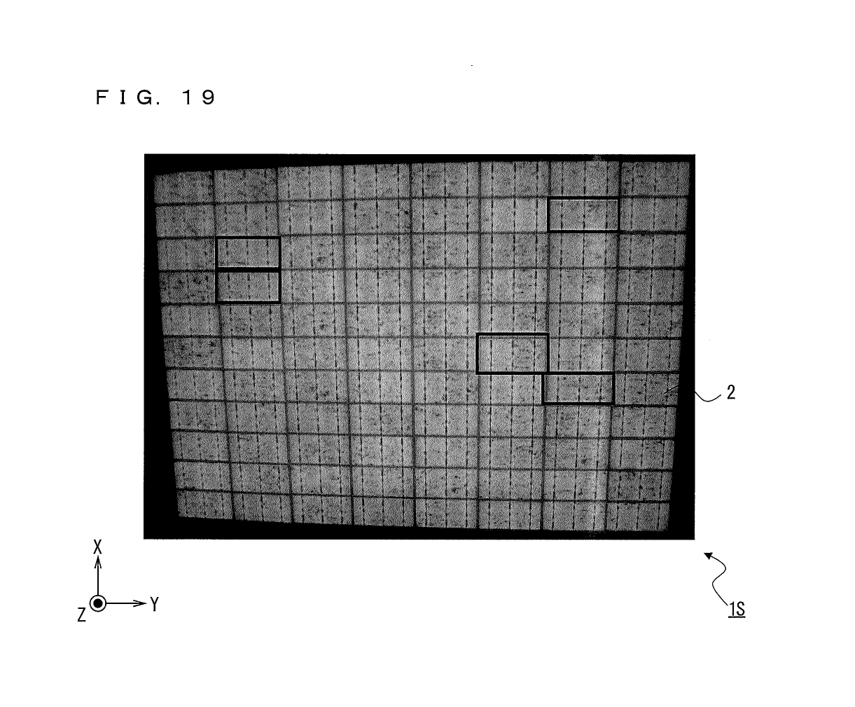

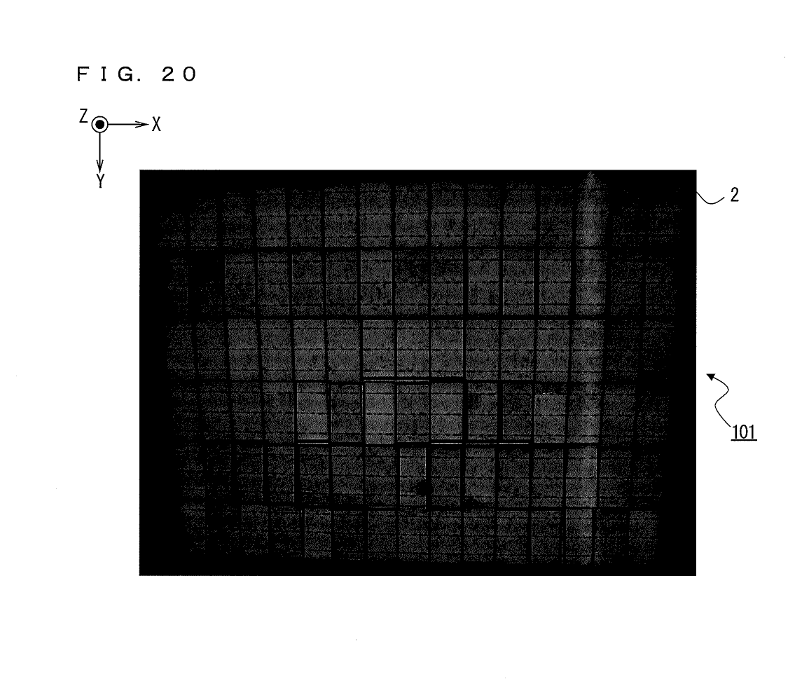

As a result, in the solar cell device 30 including the first solar cell module 1S, cracks were caused only in five solar cell elements 2 surrounded by bold lines of FIG. 19. By contrast, in the solar cell device including the second solar cell module 101, cracks were caused as many as 36 solar cell elements 2 surrounded by bold lines of FIG. 20. This shows that, in the solar cell device 30 according to this embodiment, output loss can be reduced as a result of reduced occurrence of a crack in the solar cell module 1.

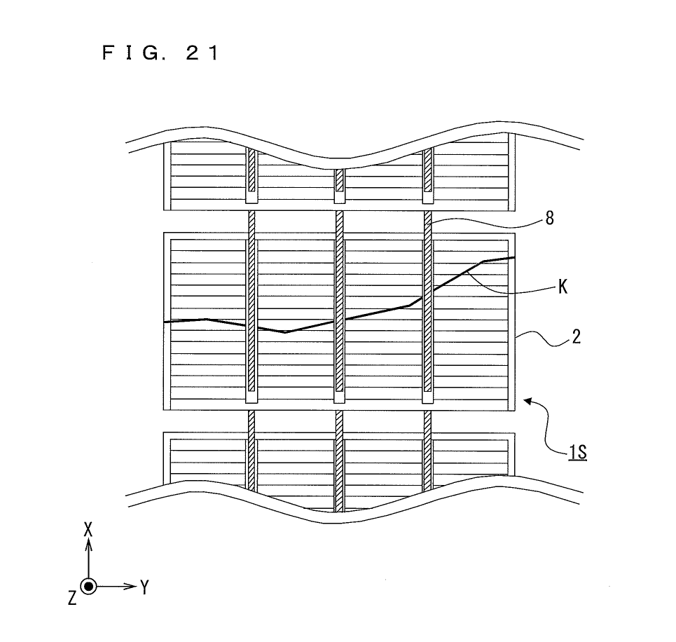

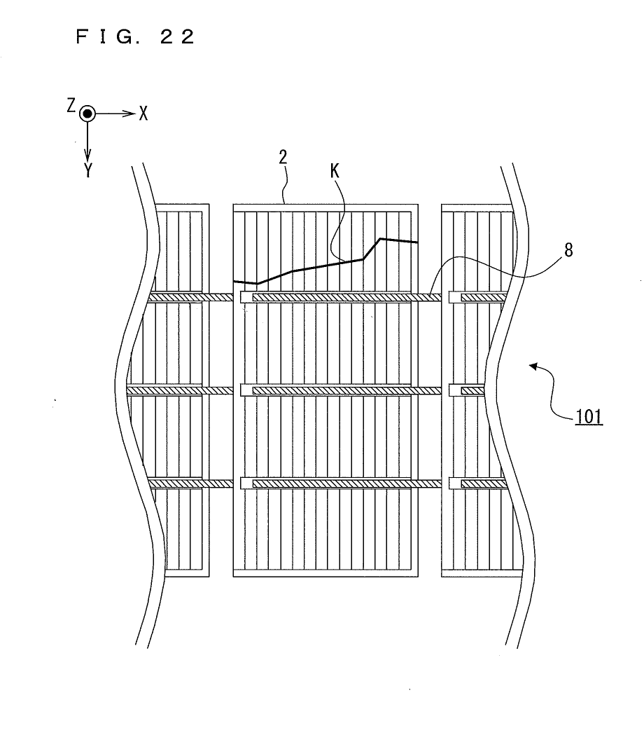

As shown in FIG. 21, in the solar cell element 2 of the first solar cell module 1S according to Example, a crack K was likely to occur in a direction (a direction along the members 7a forming the long sides of the frame 7) perpendicular to the first direction (a direction along the members 7b forming the short sides of the frame 7) in which the solar cell module 1S is mainly curved. This proves that, in the first solar cell module 1S according to Example, regions in the solar cell element 2 separated from each other by a crack K can be connected via the wiring material 8, as shown in FIG. 21. By contrast, as shown in FIG. 22, in the solar cell element 2 of the second solar cell module 101 according to Reference Example, a crack K was likely to occur in a direction (a direction along the members 7a forming the long sides of the frame 7) perpendicular to the second direction (a direction along the members 7b forming the short sides of the frame 7) in which the second solar cell module 101 is mainly curved. This proves that, in the second solar cell module 101 according to Reference Example, it is difficult to connect regions in the solar cell element 2 separated from each other by a crack K via the wiring material 8, as shown in FIG. 22. This shows that, in the first solar cell module 1S according to Example, even on the occurrence of a crack in the solar cell element 2, output loss of the solar cell module 1 can still be reduced.

### 2-6. Brief of First Embodiment

In the solar cell module 1 according to the first embodiment, in each solar cell element group 5, the solar cell elements 2 are connected in series via the wiring material 8 while the first side part 2o and the second side part 2p face each other that extend along long sides belonging to the first surfaces 2b of these solar cell elements 2, for example. This increases the number of the solar cell elements 2 connected in series in each solar cell element group 5, allowing increase in the output of the solar cell module 1. Further, the light-transmitting substrate 3 covering a plurality of solar cell element groups 5 from a direction of the first surface 2b has a rectangular surface with the short sides 3b located to extend in the first direction (−X direction) and the long sides 3a located to extend in the second direction (+Y direction). Thus, if the solar cell module 1 is supported by the first support member 311 at its end portion extending along the first long side 3a1 and is supported by the second support member 312 at its end portion extending along the second long side 3a2, for example, application of a positive pressure load or a negative pressure load on the solar cell module 1 does not cause a crack in the solar cell element 2 easily. Even if a crack occurs in the solar cell element 2, regions in this solar cell element 2 separated from each other by the crack can still be kept connected to each other by the wiring material 8. This can reduce output loss of the high-output solar cell module 1.

In the solar cell module 1 according to the first embodiment, the first side surface 2a3 of the first solar cell element 2A is arranged to face the second side surface 2a4 of the second solar cell element 2B in the first direction (−X direction), for example. The second solar cell element 2B includes the insulating layer 2g covering the second side surface 2a4, whereas the first side surface 2a3 of the first solar cell element 2A is exposed to the outside of the first solar cell element 2A, for example. In a region between the first side surface 2a3 of the first solar cell element 2A and the second side surface 2a4 of the second solar cell element 2B, the wiring material 8 is arranged in a position closer to the second side surface 2a4 of the second solar cell element 2B than to the first side surface 2a3 of the first solar cell element 2A. Thus, the wiring material 8 and the second side surface 2a4 of the semiconductor substrate 2a of the second solar cell element 2B are unlikely to contact each other directly, for example. Further, the first side surface 2a3 of the first solar cell element 2A and the wiring material 8 are unlikely contact each other, for example. Thus, while the semiconductor substrate 2a is exposed at the first side part 2o of the first solar cell element 2A, leakage current is unlikely to occur between the first side part 2o and the wiring material 8. As a result, output loss of the high-output solar cell module 1 can be reduced.

### 3. Different Embodiments

The present disclosure is not to be limited to the aforementioned first embodiment but can be changed or modified in various ways within a range that does not depart from the substance of the present disclosure.

### 3-1. Second Embodiment

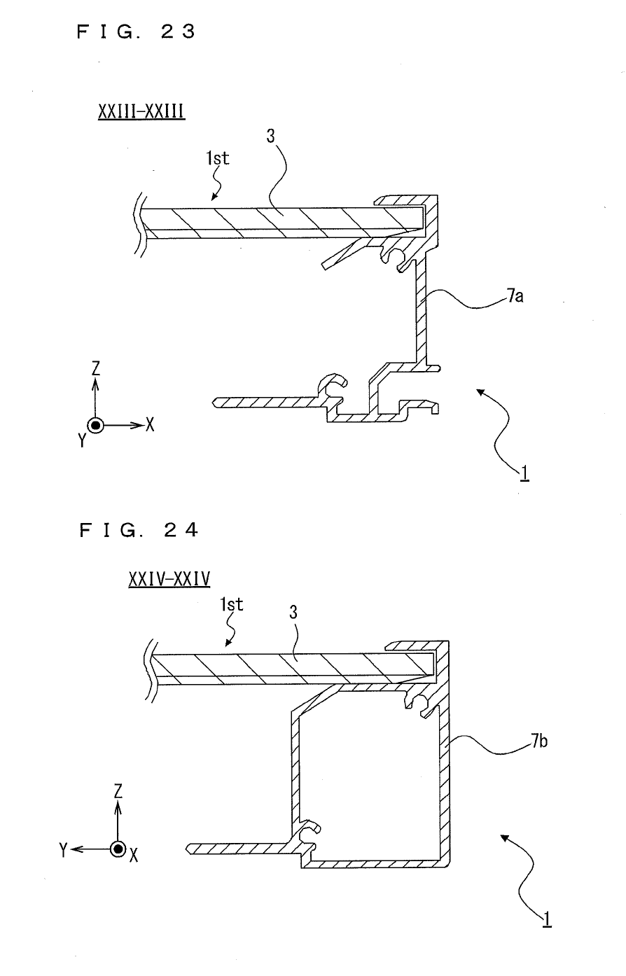

In the solar cell module 1 according to the aforementioned first embodiment, as shown in FIGS. 23 and 24, for example, the frame 7 may be configured in such a manner that the members 7b in a pair (third and fourth members 7b 1 and 7b2) forming the short sides of the frame 7 have a higher modulus of section than the members 7a in a pair (first and second members 7a1 and 7a2) forming the long sides of the frame 7.

According to the configuration of this embodiment, if a positive pressure load or a negative pressure load is applied to the solar cell device 30, displacement by deflection can be reduced in the members 7b in a pair (third and fourth members 7b1 and 7b2) that are stretched between the support members 31 in a pair and are mainly likely to deflect to be curved. This can reduce the occurrence of a crack in the solar cell element 2. The modulus of section of the members 7a in a pair (first and second members 7a1 and 7a2) and that of the members 7b in a pair (third and fourth members 7b 1 and 7b2) forming the frame 7 can be calculated based on a cross-sectional structure perpendicular to the longitudinal direction of each of these members drawn by a CAD (computer-aided design), for example.

### 3-2. Third Embodiment

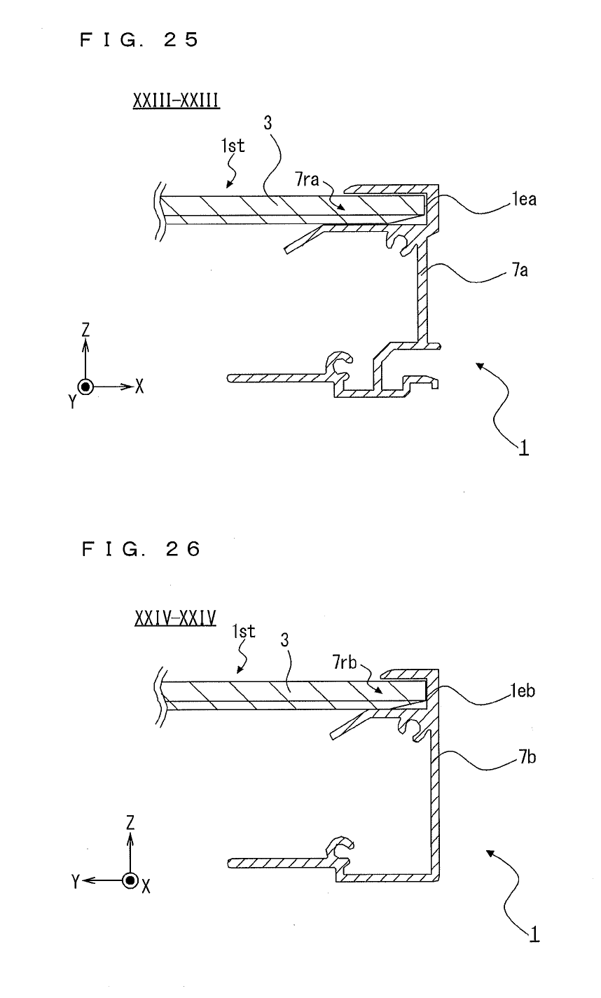

In the aforementioned first and second embodiments, as shown in FIG. 25, for example, each of the members 7a forming the long sides of the frame 7 has a recess 7ra in which an end portion lea of the stack 1st of the solar cell module 1 extending along the long side 3a is fitted. More specifically, the first member 7a1 of the frame 7 has a first recess 7ra in which a first end portion lea of the stack 1st of the solar cell module 1 extending along the long side 3a belonging to the −X side (first long side 3a1) is fitted. The second member 7a2 of the frame 7 has a second recess 7ra in which a second end portion lea of the stack 1st of the solar cell module 1 extending along the long side 3a belonging to the +X side (second long side 3a2) is fitted. Specifically, portions of the light-transmitting substrate 3 along the long sides 3a are fitted in the recesses 7ra.

As shown in FIG. 26, for example, each of the members 7b forming the short sides of the frame 7 has a recess 7rb in which an end portion 1eb of the stack 1st of the solar cell module 1 extending along the short side 3b is fitted. More specifically, the third member 7b1 of the frame 7 has a third recess 7rb in which a third end portion 1eb of the stack 1st of the solar cell module 1 extending along the short side 3b belonging to the −Y side (first short side 3b1) is fitted. The fourth member 7b2 of the frame 7 has a fourth recess 7rb in which a fourth end portion 1eb of the stack 1st of the solar cell module 1 extending along the short side 3b belonging to the +Y side (second short side 3b2) is fitted. Specifically, portions of the light-transmitting substrate 3 along the short sides 3b are fitted in the recesses 7rb.

As shown in FIGS. 25 and 26, for example, the depth of the first recess 7ra in the first direction (−X direction) and that of the second recess 7ra in the first direction (−X direction) may be set to be greater than the depth of the third recess 7rb in the second direction (+Y direction) and that of the fourth recess 7rb in the second direction (+Y direction). By doing so, the area of a hidden region of a light-receiving part of the solar cell module 1 is reduced using the third and fourth members 7b1 and 7b2, for example. Here, if a positive pressure load and a negative pressure load are applied to the solar cell device 30, resultant deflection of the solar cell module 1 reduces the length of the solar cell module 1 in the first direction (−X direction). Meanwhile, a sufficient depth is ensured in the first direction (−X direction) at each of the first and second recesses 7ra. This can make it unlikely that the stack 1st including the light-transmitting substrate 3 and the sheet member 6 will fall off the first and second members 7a1 and 7a2.

### 3-3. Fourth Embodiment

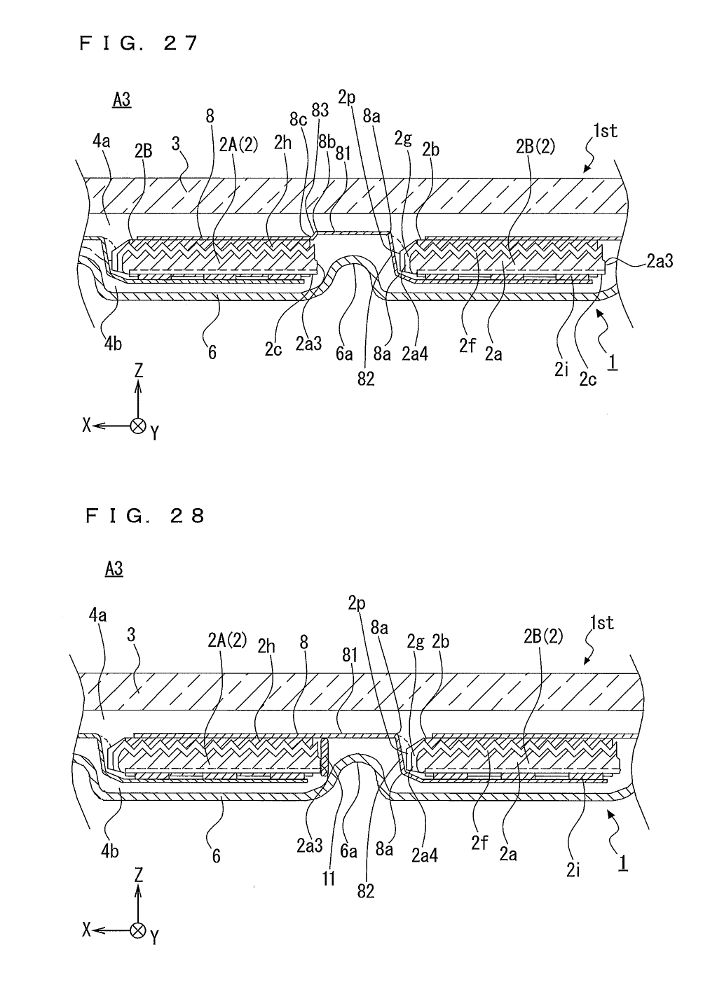

In each of the aforementioned embodiments, as shown in FIG. 27, for example, the wiring material 8 may have a third part 83 extending from a direction of the first surface 2b of the first solar cell element 2A toward the light-transmitting substrate 3, and a bent part (also called a second bent part) 8b connecting the third part 83 and the first part 81. The second bent part 8b is arranged in a position closer to the first side surface (exposed part) 2a3 of the first solar cell element 2A than to the second side surface 2a4 of the second solar cell element 2B.

More specifically, as shown in FIG. 27, for example, in the wiring material 8, the second bent part 8b is arranged at an end portion of the third part 83 closer to the light-transmitting substrate 3, whereas a third bent part 8c is arranged at an end portion of the third part 83 closer to the first solar cell element 2A. This forms a part of a crank shape in the wiring material 8 that forms connection between a part of the wiring material 8 connected to the front-side busbar electrode 2h of the first solar cell element 2A and the first part 81 of the wiring material 8 between the first and second solar cell elements 2A and 2B. The second and third bent parts 8b and 8c can be formed by press working on the wiring material 8 performed in advance, for example.

For example, on a line of extension in the first direction (−X direction) of the part of the wiring material 8 connected to the front-side busbar electrode 2h of the first solar cell element 2A, the third bent part 8c is arranged in a position closer to the first side surface (exposed part) 2a3 of the first solar cell element 2A than to the second side surface 2a4 of the second solar cell element 2B. Further, the third part 83 is arranged in a position closer to the first side surface (exposed pare 2a3 of the first solar cell element 2A than to the second side surface 2a4 of the second solar cell element 2B, for example. Thus, the second bent part 8b is also arranged in a position closer to the first side surface (exposed part) 2a3 of the first solar cell element 2A than to the second side surface 2a4 of the second solar cell element 2B, for example. Further, the second and third bent parts 8b and 8c are arranged in the front-side sealing material 4a contacting the light-transmitting substrate 3, for example.

For example, a first level difference between the part of the wiring material 8 connected to the front-side busbar electrode 2h of the first solar cell element 2A and the first part 81 of the wiring material 8 between the first and second solar cell elements 2A and 2B (a shift in the +Z direction) is smaller than a second level difference between a part of the wiring material 8 connected to the back-side busbar electrode 2i of the second solar cell element 2B and the first part 81 of the wiring material 8 (a shift in the +Z direction). If the first level difference determined before the laminating step is larger than a distance between the first surface 2b of the first solar cell element 2A and the light-transmitting substrate 3 of the solar cell module 1, for example, the front-side sealing material 4a strongly presses the second bent part 8b locally in the laminating step to apply excessive stress to the first solar cell element 2A via the wiring material 8. In this case, a crack is likely to occur in the first solar cell element 2A. Thus, if the first level difference determined before the laminating step is smaller than the distance between the first surface 2b of the first solar cell element 2A and the light-transmitting substrate 3 of the solar cell module 1, the force of the front-side sealing material 4a pressing the second bent part 8b locally is reduced and the wiring material 8 can be separated from the first side surface (exposed part) 2a3 of the first solar cell element 2A. If this configuration is employed, the first level difference can be set to be smaller than the thickness of the solar cell element 2, for example. If the thickness of the solar cell element 2 is 0.18 mm, the first level difference can be set at 0.1 mm, for example.

As described above, in this embodiment, the wiring material 8 is separated from the first side surface (exposed part) 2a3 of the first solar cell element 2A by the provision of the third part 83 and the second bent part 8b to the wiring material 8, for example. This can reduce the occurrence of leakage current due to contact between the wiring material 8 and the first side surface (exposed part) 2a3. As a result, output loss of the solar cell module 1 can be reduced.

### 3-4. Fifth Embodiment

In each of the aforementioned embodiments, as shown in FIG. 28, for example, an insulating member 11 may be provided further in a region between the first side surface 2a3 of the first solar cell element 2A and the second side surface 2a4 of the second solar cell element 2B and in a position between the first side surface 2a3 of the first solar cell element 2A and the wiring material 8. This can reduce the occurrence of leakage current due to contact between the wiring material 8 and the first side surface (exposed part) 2a3. As a result, output loss of the solar cell module 1 can be reduced.

The insulating member 11 can be made of a material having insulating properties such as resin, for example. By being attached to the wiring material 8 in advance, for example, the insulating member 11 can be arranged in an appropriate position in the solar cell module 1.

### 3-5. Sixth Embodiment

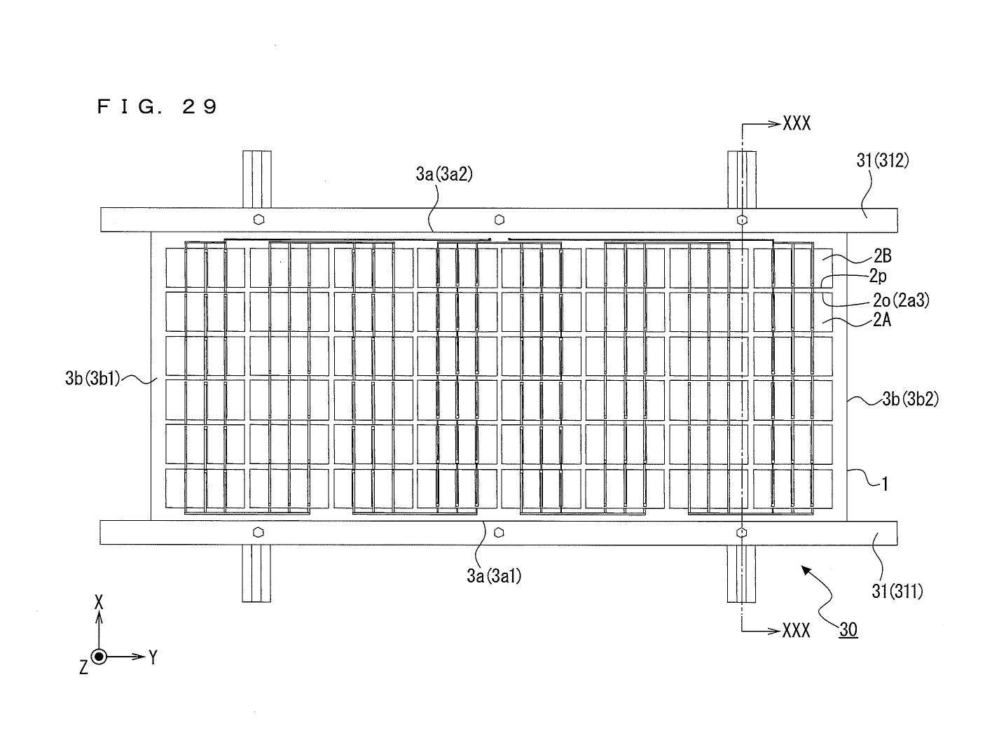

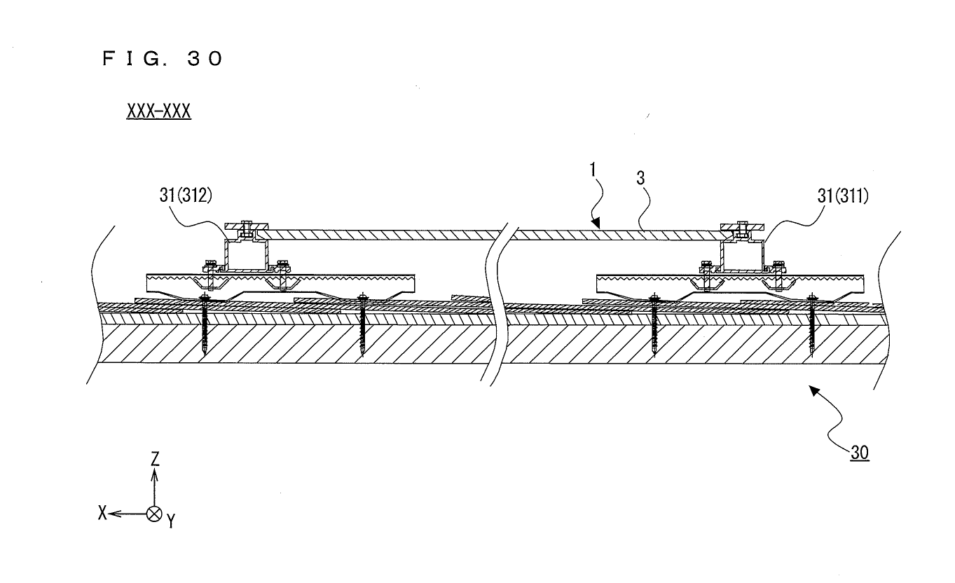

In each of the aforementioned embodiments, as shown in FIGS. 29 and 30, the frame 7 may be omitted from the solar cell module 1, for example.

In this case, the frame 7 including the first and second members 7a1 and 7a2 attached to the long sides 3a in a pair of the solar cell module 1 is omitted from the solar cell device 30, for example. For example, in the structure of this solar cell device 30, the elongated support member 31 is provided to extend in the longitudinal direction of the long side 3a of the light-transmitting substrate 3 and a part of the light-transmitting substrate 3 extending along the long side 3a is supported by means of contact with the support member 31. Specifically, the solar cell device 30 includes the support member (first support member) 31 arranged to support an end portion of the solar cell module 1 along the first long side 3a1, and the support member (second support member) 31 arranged to support an end portion of the solar cell module 1 extending along the second long side 3a2, for example.

Like in the aforementioned first embodiment, this structure can also reduce the occurrence of a crack in the solar cell element 2 of the solar cell module 1. As a result, output loss of the solar cell module 1 can be reduced.

Some or all of the respective structures of all the aforementioned embodiments can certainly be combined, if appropriate, within a range in which contradiction does not arise.

1. A solar cell module comprising:
a plurality of solar cell element groups each including a plurality of solar cell elements and a wiring material, the solar cell elements being aligned in a first direction and each having a rectangular first surface and a rectangular second surface on the back side of the first surface, the wiring material electrically connecting a first solar cell element and a second solar cell element belonging to the solar cell elements and being adjacent to each other in the first direction;
a light-transmitting substrate located to cover the solar cell element groups from a direction of the first surface;
a back-side protective member located to cover the solar cell element groups from a direction of the second surface;
a first sealing material located between the light-transmitting substrate and the solar cell element groups; and
a second sealing material located between the solar cell element groups and the back-side protective member, wherein
the solar cell element groups are aligned in a second direction perpendicular to the first direction,
each of the solar cell elements includes four side parts connecting the first and second surfaces to each other,
the four side parts include a first side part, a second side part on the back side of the first side part, a third side part, and a fourth side part on the back side of the third side part,
each of the third and fourth side parts located along the first direction,
each of the first and second side parts located along the second direction,
the length of the first side part in the second direction and the length of the second side part in the second direction are larger than the length of the third side part in the first direction and the length of the fourth side part in the first direction,
in each of the solar cell element groups, the solar cell elements are located in such a manner that the first side part and the second side part belonging to the solar cell elements face each other,
the wiring material is electrically connected to the first surface of the first solar cell element along the first direction and the wiring material is electrically connected to the second surface of the second solar cell element along the first direction, and
the light-transmitting substrate has a first short side and a second short side each being located along the first direction, and a first long side and a second long side each being located along the second direction.

2. The solar cell module according to claim 1, further comprising a frame including a first member, a second member, a third member, and a fourth member, the first member being attached to a stack along the first long side, the stack including the light-transmitting substrate, the first sealing material, the solar cell element groups, the second sealing material, and the back-side protective member, the second member being attached to the stack along the second long side, the third member being attached to the stack along the first short side, the fourth member being attached to the stack along the second short side.

3. The solar cell module according to claim 2, wherein the third and fourth members have a higher modulus of section than the first and second members.

4. The solar cell module according to claim 2, wherein
the first member has a first recess in which a first end portion of the stack along the first long side is fitted,
the second member has a second recess in which a second end portion of the stack extending along the second long side is fitted,
the third member has a third recess in which a third end portion of the stack along the first short side is fitted,
the fourth member has a fourth recess in which a fourth end portion of the stack extending along the second short side is fitted, and
the depth of the first recess in the first direction and the depth of the second recess in the first direction are greater than the depth of the third recess in the second direction and the depth of the fourth recess in the second direction.

5. A solar cell device comprising:
the solar cell module as recited in claim 1;
a first support member located at an end portion of the solar cell module along the first long side; and
a second support member located at an end portion of the solar cell module along the second long side.

6. A solar cell module comprising:
a solar cell element group including a first solar cell element, a second solar cell element, and a wiring material, the first and second solar cell elements being aligned in a first direction and each having a rectangular first surface and a rectangular second surface on the back side of the first surface, the wiring material electrically connecting the first surface of the first solar cell element and the second surface of the second solar cell element;
a light-transmitting substrate located to cover the solar cell element group from a direction of the first surface;
a back-side protective member located to cover the solar cell element group from a direction of the second surface;
a first sealing material located between the light-transmitting substrate and the solar cell element group; and
a second sealing material located between the solar cell element group and the back-side protective member, wherein
each of the first and second solar cell elements includes a semiconductor substrate having a first substrate surface located on the first surface side, a second substrate surface located on the back side of the first substrate surface, a first side surface connecting the first and second substrate surfaces, and a second side surface located on the back side of the first side surface and connecting the first and second substrate surfaces,
the first side surface of the first solar cell element is located to face the second side surface of the second solar cell element in the first direction,
the second solar cell element includes an insulating layer covering the second side surface of the second solar cell element,
the first side surface of the first solar cell element is exposed to the outside of the first solar cell element, and
in a region between the first side surface of the first solar cell element and the second side surface of the second solar cell element, the wiring material is located in a place closer to the second side surface of the second solar cell element than to the first side surface of the first solar cell element.

7. The solar cell module according to claim 6, wherein the wiring material includes:
a first part located to approach from a direction of the first surface of the first solar cell element to the first surface of the second solar cell element in the first direction;
a second part located to approach from a direction of the light-transmitting substrate toward the back-side protective member; and
a first bent part connecting the first and second parts while being located in a position closer to the second side surface of the second solar cell element than to the first side surface of the first solar cell element.

8. The solar cell module according to claim 7, wherein the wiring material includes:
a third part located to approach from a direction of the first surface of the first solar cell element toward the light-transmitting substrate; and
a second bent part connecting the third and first parts.

9. The solar cell module according to claim 6, further comprising an insulating member located in the region between the first side surface of the first solar cell element and the second side surface of the second solar cell element and in a position between the first side surface of the first solar cell element and the wiring material.
